(19) United States
(12) Patent Application Publication
(10) Pub. No.: US 2025/0096027 A1
(43) Pub. Date: Mar. 20, 2025

(54) SUBSTRATE PEELING DEVICE, SUBSTRATE PEELING METHOD, AND METHOD OF MANUFACTURING SEMICONDUCTOR DEVICE

(71) Applicant: Kioxia Corporation, Tokyo (JP)

(72) Inventor: Yoshio MIZUTA, Yokkaichi Mie (JP)

(73) Assignee: Kioxia Corporation, Tokyo (JP)

(21) Appl. No.: 18/820,760

(22) Filed: Aug. 30, 2024

(30) Foreign Application Priority Data
Sep. 15, 2023 (JP) 2023-150344

(51) Int. Cl. H01L 21/683; H01L 21/687

(52) U.S. Cl. CPC H01L 21/6835; H01L 21/68742; H01L 2221/68386

(57) ABSTRACT

According to one embodiment, a substrate peeling device including an adsorption stage and a light source is provided. A bonded body including multiple substrates is adsorbed to the adsorption stage. The adsorption stage includes a first region and a second region. The second region is inside the first region. The light source can sequentially apply a laser beam toward the first region and the second region. The adsorption stage has weaker power of adsorbing the bonded body in the second region than in the first region.

### CROSS-REFERENCE TO RELATED APPLICATIONS

This application is based upon and claims the benefit of Japanese Patent Application No. 2023-150344, filed on May 9, 2023; the entire contents of which are incorporated herein by reference.

### FIELD

Embodiments described herein relate generally to a substrate peeling device, a substrate peeling method, and a method of manufacturing a semiconductor device.

### BACKGROUND

When a semiconductor device is manufactured, two substrates may be bonded, and then one of the two substrates may be peeled by applying a laser beam (laser peeling). In a substrate peeling device that performs the laser peeling, it is desired that the substrate is appropriately peeled.

### BRIEF DESCRIPTION OF THE DRAWINGS

FIG. 1 illustrates a schematic configuration of a substrate peeling device according to a first embodiment;

FIG. 2 is a cross-sectional view illustrating a configuration of an adsorption stage in the first embodiment;

FIG. 3 is a plan view illustrating the configuration of the adsorption stage in the first embodiment;

FIG. 4 is an enlarged cross-sectional view illustrating a configuration near the center of the adsorption stage in the first embodiment;

FIG. 5 is an enlarged plan view illustrating a configuration near the center of the adsorption stage in the first embodiment;

FIG. 6 is a flowchart illustrating a method of manufacturing a semiconductor device in a variation of the first embodiment;

FIGS. 7A to 7E are cross-sectional views illustrating the method of manufacturing a semiconductor device in the variation of the first embodiment;

FIGS. 8A and 8B are enlarged cross-sectional views illustrating the method of manufacturing a semiconductor device in the variation of the first embodiment;

FIGS. 9A and 9B are cross-sectional views illustrating the method of manufacturing a semiconductor device in the variation of the first embodiment;

FIG. 10 is an enlarged cross-sectional view illustrating the method of manufacturing a semiconductor device in the variation of the first embodiment;

FIGS. 11A to 11D are plan views illustrating the method of manufacturing a semiconductor device in the variation of the first embodiment;

FIGS. 12A to 12C are cross-sectional views illustrating the method of manufacturing a semiconductor device in the variation of the first embodiment;

FIGS. 13A to 13C are cross-sectional views illustrating the method of manufacturing a semiconductor device in the variation of the first embodiment;

FIG. 14 is a cross-sectional view illustrating stress relaxation in the variation of the first embodiment;

FIG. 15 is an enlarged cross-sectional view illustrating the stress relaxation in the variation of the first embodiment;

FIGS. 16A to 16E are cross-sectional views illustrating the method of manufacturing a semiconductor device in the variation of the first embodiment;

FIG. 17 is an enlarged cross-sectional view illustrating the method of manufacturing a semiconductor device in the variation of the first embodiment;

FIG. 18 illustrates a schematic configuration of a substrate peeling device according to a second embodiment;

FIG. 19 is a cross-sectional view illustrating a configuration of an adsorption stage in the second embodiment;

FIG. 20 is a plan view illustrating the configuration of the adsorption stage in the second embodiment;

FIG. 21 is a cross-sectional view illustrating a configuration of a center region in the second embodiment;

FIG. 22 is an enlarged plan view illustrating the configuration of the center region in the second embodiment;

FIG. 23 is a cross-sectional view illustrating stress relaxation in a variation of the second embodiment;

FIG. 24 is an enlarged cross-sectional view illustrating the stress relaxation in the variation of the second embodiment;

FIGS. 25A to 25D are plan views illustrating a method of manufacturing a semiconductor device in a third embodiment; and

FIGS. 26A and 26B are cross-sectional views illustrating the method of manufacturing a semiconductor device in the third embodiment.

### DETAILED DESCRIPTION

In general, according to one embodiment, a substrate peeling device including an adsorption stage and a light source is provided. A bonded body including multiple substrates is adsorbed to the adsorption stage. The adsorption stage includes a first region and a second region. The second region is inside the first region. The light source can sequentially apply a laser beam toward the first region and the second region. The adsorption stage has weaker power of adsorbing the bonded body in the second region than in the first region.

Exemplary embodiments of a substrate peeling device will be explained below in detail with reference to the accompanying drawings. The present invention is not limited to the following embodiments.

### First Embodiment

A substrate peeling device according to a first embodiment is used for peeling one of two substrates bonded in manufacturing of a semiconductor device by applying a laser beam (laser peeling). Efforts are made to appropriately peel the substrate.

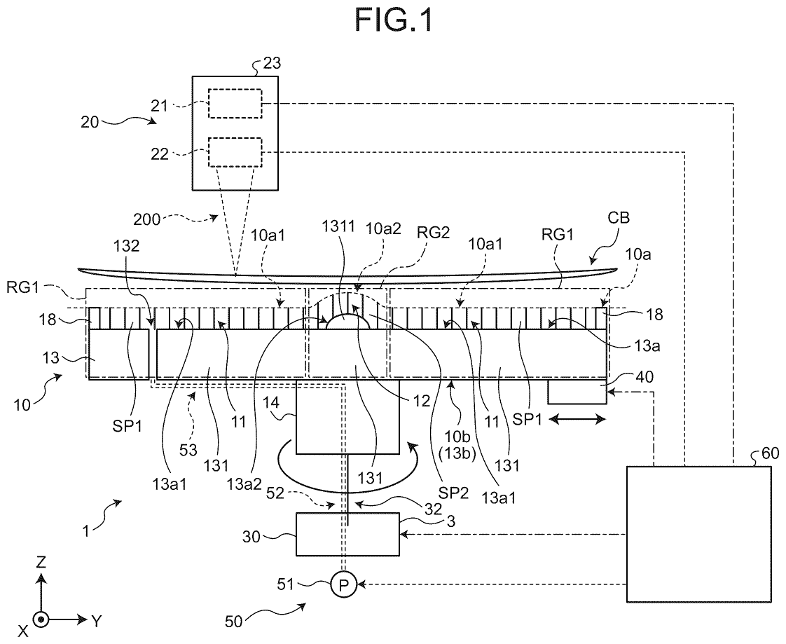

A substrate peeling device 1 can be configured as illustrated in FIG. 1. FIG. 1 illustrates a schematic configuration of the substrate peeling device 1.

The substrate peeling device 1 includes an adsorption stage 10, a laser module 20, a driver 30, a driver 40, an exhaust device 50, and a controller 60. In the following description, a direction perpendicular to a bottom surface 10b of the adsorption stage 10 is defined as a Z direction, and two directions orthogonal to each other in a plane perpendicular to the Z direction are defined as an X direction and a Y direction.

The controller 60 integrally controls units of the substrate peeling device 1.

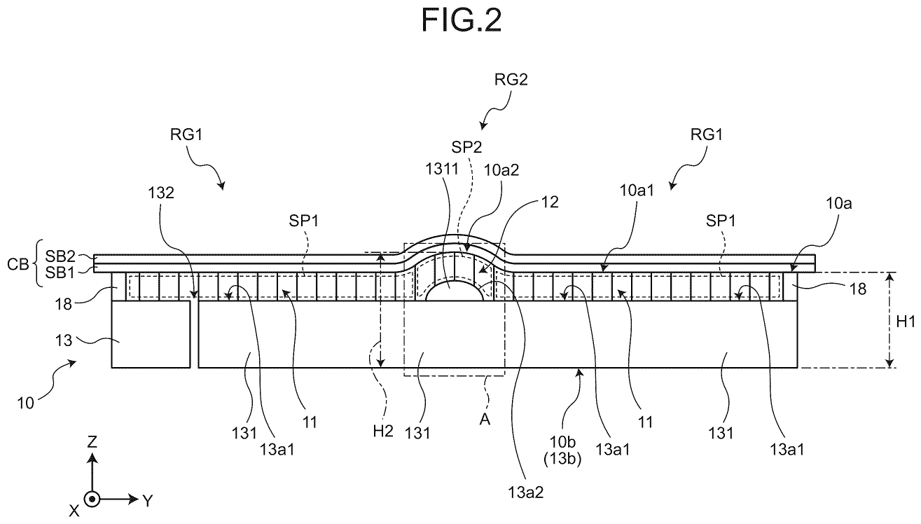

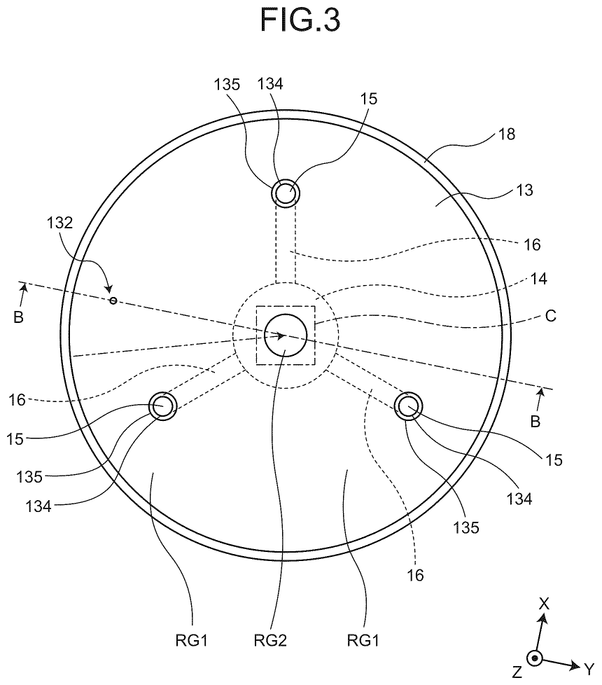

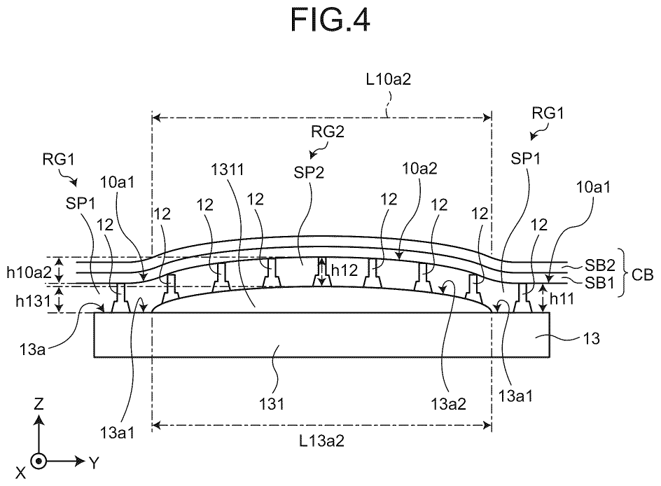

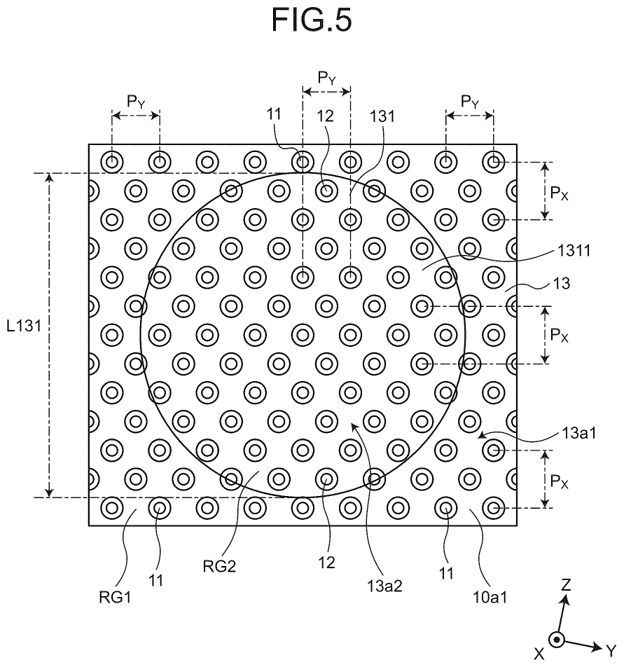

As illustrated in FIGS. 2 to 5, the adsorption stage 10 can adsorb a bonded body (combined body) CB. FIG. 2 is a YZ cross-sectional view illustrating a configuration of the adsorption stage 10. FIG. 3 is an XY plan view illustrating the configuration of the adsorption stage 10. The YZ cross-sectional view of FIG. 2 corresponds to a cross section taken along line B-B in FIG. 3. FIG. 4 is a YZ enlarged cross-sectional view illustrating a configuration near the center of the adsorption stage 10, and corresponds to a YZ cross-sectional view obtained by enlarging a portion A in FIG. 2. FIG. 5 is an XY enlarged plan view illustrating the configuration near the center of the adsorption stage 10, and corresponds to a plan view obtained by enlarging a portion C in FIG. 3.

The adsorption stage 10 includes a region RG1 and a region RG2. The region RG2 is provided inside the region RG1 in an XY direction.

The adsorption stage 10 has an adsorption surface 10a and the bottom surface 10b. The adsorption surface 10a is provided on a +Z side of the adsorption stage 10. The adsorption surface 10a extends substantially along the XY direction. The adsorption surface 10a is substantially flat, but slightly raised near the center. The bottom surface 10b is provided on a side opposite to the adsorption surface 10a (−Z side) of the adsorption stage 10. The bottom surface 10b extends along the XY direction. The bottom surface 10b is substantially flat.

The bonded body CB is adsorbed to the adsorption surface 10a. The adsorption stage 10 may adsorb the bonded body CB to the adsorption surface 10a by forming a reduced-pressure atmosphere between the bonded body CB and the adsorption stage 10. The reduced-pressure atmosphere refers to an atmosphere having a pressure of 10 Pa or less. In the bonded body CB, multiple substrates SB1 and SB2 is stacked and bonded to each other. FIG. 2 illustrates a state in which the adsorption stage 10 absorbs the bonded body CB to the adsorption surface 10a. The bonded body CB may have a substantially circular shape in XY plan view. Correspondingly, the adsorption surface 10a may have a substantially circular shape in XY plan view.

The adsorption surface 10a includes a flat surface 10a1 and a protruding surface 10a2. The flat surface 10a1 is disposed in the region RG1. The protruding surface 10a2 is disposed in the region RG2. The protruding surface 10a2 is disposed inside the flat surface 10a1 in the XY direction. In the adsorption stage 10, a height H2 of the protruding surface 10a2 from the bottom surface 10b is greater than a height H1 of the flat surface 10a1 from the bottom surface 10b (see FIG. 2). The flat surface 10a1 extends flat in the XY direction. The protruding surface 10a2 extends substantially in the XY direction while protruding from the flat surface 10a1 toward the +Z side.

This enables compression stress headed from the adsorption stage 10 toward the bonded body CB near the protruding surface 10a2 to selectively act in a situation where tensile stress headed from the bonded body CB toward the adsorption stage 10 acts on the adsorption surface 10a at the time when the bonded body CB is adsorbed. As a result, the adsorption stage 10 can have weaker power of adsorbing the bonded body CB in the region RG2 than in the region RG1.

The adsorption stage 10 further includes multiple support pins 11, multiple support pins 12, a stage base 13, a partition wall 18, a support member (stage support) 14, multiple lift pins 15, and multiple frames 16.

The stage base 13 has a main surface 13a and a bottom surface 13b. The main surface 13a is provided on the +Z side of the stage base 13. The main surface 13a extends substantially along the XY direction. The main surface 13a is substantially flat, but slightly raised near the center. The main surface 13a may have a substantially circular shape in XY plan view. The bottom surface 13b is provided on a side opposite to the main surface 13a (−Z side) of the stage base 13. The bottom surface 13b extends along the XY direction. The bottom surface 13b is substantially flat. The bottom surface 13b may be the same as the bottom surface 10b of the adsorption stage 10.

The main surface 13a is located on the −Z side of the adsorption surface 10a. The main surface 13a may extend substantially in the XY direction along the adsorption surface 10a. A substantially constant Z interval may be provided between the main surface 13a and the adsorption surface 10a.

The main surface 13a includes a flat surface 13a1 and a protruding surface 13a2. The flat surface 13a1 is disposed in the region RG1. The protruding surface 13a2 is disposed in the region RG2. The protruding surface 13a2 is disposed inside the flat surface 13a1 in the XY direction. The height of the protruding surface 13a2 from the bottom surface 13b may be greater than the height of the flat surface 13a1 from the bottom surface 13b. The flat surface 13a1 extends flat in the XY direction. The protruding surface 13a2 extends substantially in the XY direction while protruding from the flat surface 13a1 toward the +Z side. That is, the flat surface 13al and the protruding surface 13a2 of the main surface 13a extend in correspondence with to the flat surface 10a1 and the protruding surface 10a2 of the adsorption surface 10a, respectively. As a result, the substantially constant Z interval can be provided between the main surface 13a and the adsorption surface 10a.

The stage base 13 includes a main body portion 131 and a protrusion 1311. The main body portion 131 is a substantially flat plate-like member, and extends substantially flat in the XY direction in the region RG1 and the region RG2. The main body portion 131 may have a substantially circular shape in XY plan view.

The protrusion 1311 is a protruding member, and is disposed on the +Z side of the main body portion 131 in the region RG2. The protrusion 1311 may cover the main body portion 131 in the region RG2 from the +Z side. The protrusion 1311 may be integrated with the main body portion 131. The protrusion 1311 may have a substantially circular shape in XY plan view.

A portion not covered with the protrusion 1311 of a surface of the main body portion 131 on the +Z side and a surface of the protrusion 1311 on the +Z side form the main surface 13a of the stage base 13. A surface of the main body portion 131 on the −Z side forms the bottom surface 13b of the stage base. An upper surface of the portion not covered with the protrusion 1311 of the surface of the main body portion 131 on the +Z side corresponds to the main surface flat surface 13a1. An upper surface of the protrusion 1311 on the +Z side corresponds to the protruding surface 13a2.

The partition wall 18 is disposed on an outer peripheral portion of the flat surface 13al of the main surface 13a. The partition wall 18 annularly extends along the outer peripheral portion of the main body portion 131. A partition wall portion 133 protrudes from the outer peripheral portion of the main surface 13a toward the +Z side.

Recessed space is formed on the +Z side of the stage base 13 by being surrounded by the main surface 13a and the partition wall 18.

Recessed space SP1 is formed by being surrounded by the flat surface 13al and the partition wall 18. Recessed space SP2 is formed by being surrounded by the protruding surface 13a2 and the partition wall 18. The recessed space SP1 is recessed from the adsorption surface 10a toward the −Z side in the region RG1. The flat surface 13al forms a bottom surface of the recessed space SP1. The recessed space SP2 is recessed from the adsorption surface 10a toward the −Z side in the region RG2. The protruding surface 13a2 forms a bottom surface of the recessed space SP2.

The multiple support pins 11 are arranged in the recessed space SP1 in the region RG1. The multiple support pins 11 are arranged on the flat surface 13a1. Each of the support pins 11 protrudes from the flat surface 13a1 in the Z direction. This enables each of the support pins 11 to support the bonded body CB in the region RG1 from the −Z side at the time when the bonded body CB is adsorbed to the adsorption surface 10a.

The multiple support pins 11 may have a Z height h11 equal to each other. Each of the support pins 11 may have the Z height h11 equal to a Z height of the partition wall 18. The Z height h11 of each of the support pins 11 may be, for example, 1 to 10 μm. The multiple support pins 11 are arranged in the XY direction in the region RG1. X-direction arrangement pitches P_{X} between the multiple support pins 11 may be equal to each other. An X-direction arrangement pitch P_{X} between a pair of support pins 11 may be, for example, 1 to 5 mm. Y-direction arrangement pitches P_{Y} between the multiple support pins 11 may be equal to each other. A Y-direction arrangement pitch P_{Y} between a pair of support pins 11 may be, for example, 1 to 5 mm. Each of the support pins 11 has a top surface extending flat along the flat surface 13a1. The multiple support pins 11 have top surfaces forming the flat surface 10a1.

The multiple support pins 12 are arranged in the recessed space SP2 in the region RG2. The bottom surface of the recessed space SP2 is raised from the bottom surface of the recessed space SP1 due to the influence of the protrusion 1311. The multiple support pins 12 are arranged on the protruding surface 13a2. Each of the support pins 12 protrudes from the protruding surface 13a2 in the Z direction. This enables each of the support pins 12 to support the bonded body CB in the region RG2 from the −Z side at the time when the bonded body CB is adsorbed to the adsorption surface 10a.

The multiple support pins 12 may have a Z height h12 equal to each other. Each of the support pins 12 may have the Z height h12 equal to the Z height of the partition wall 18. Each of the support pins 12 may have the Z height h12 of, for example, 1 to 10 μm. The multiple support pins 12 are arranged in the XY direction in the region RG2. X-direction arrangement pitches P_{X} between the multiple support pins 12 may be equal to each other. An X-direction arrangement pitch P_{X} between a pair of support pins 12 may be, for example, 1 to 5 mm. Y-direction arrangement pitches P_{Y} between the multiple support pins 12 may be equal to each other. A Y-direction arrangement pitch P_{Y} between a pair of support pins 12 may be, for example, 1 to 5 mm. Each of the support pins 12 has a top surface extending in a protruding manner along the protruding surface 13a2. The multiple support pins 12 have top surfaces forming the protruding surface 10a2.

In YZ cross-sectional view, the protruding surface 13a2 of the main surface 13a may protrude from the flat surface 13a1 toward the +Z side in a curved surface shape, may protrude from the flat surface 13a1 toward the +Z side in a columnar shape, may protrude from the flat surface 13a1 toward the +Z side in a prismatic shape, may protrude from the flat surface 13al toward the +Z side in a conical shape, or may protrude from the flat surface 13a1 toward the +Z side in a pyramidal shape. FIGS. 1 and 2 illustrate a configuration in which the protruding surface 13a2 protrudes from the flat surface 13al in a curved surface shape.

A Z height h131 of the protruding surface 13a2 from the flat surface 13al may be, for example, 1 to 10 μm.

The Z height h11 of each of the support pins 11 and the Z height h12 of each of the support pins 12 may be equal to each other. Each of the support pins 11 is disposed on the flat surface 13al, whereas each of the support pins 12 is disposed on the protruding surface 13a2. Therefore, the multiple support pins 12 are raised as compared to the multiple support pins 11. The top surfaces and extended surfaces thereof of the multiple support pins 11 form the flat surface 10a1 in the region RG1. The top surfaces and extended surfaces thereof of the multiple support pins 12 form the protruding surface 10a2 in the region RG2.

Accordingly, the protruding surface 10a2 and the flat surface 10a1 of the adsorption surface 10a may extend along the protruding surface 13a2 and the flat surface 13a1 of the main surface 13a, respectively. That is, the protruding surface 10a2 may protrude from the flat surface 10a1 toward the +Z side in a curved surface shape, may protrude from the flat surface 10a1 toward the +Z side in a columnar shape, may protrude from the flat surface 10a1 toward the +Z side in a prismatic shape, may protrude from the flat surface 10a1 toward the +Z side in a conical shape, or may protrude from the flat surface 10a1 toward the +Z side in a pyramidal shape. FIGS. 1 and 2 illustrate a configuration in which the protruding surface 10a2 protrudes from the flat surface 10a1 in a curved surface shape.

A Z height h10a2 of the protruding surface 10a2 from the flat surface 10a1 may be, for example, 1 to 10 μm.

The protruding surface 13a2 may have a substantially circular shape in XY plan view. The protruding surface 13a2 may have a maximum XY width (e.g., diameter in XY plan view) L13a2 of 10 mm or less, for example, 5 to 10 mm.

The protruding surface 10a2 may have a substantially circular shape in XY plan view. The protruding surface 10a2 may have a maximum XY width (e.g., diameter in XY plan view) L10a2 of 10 mm or less, for example, 5 to 10 mm.

Here, as illustrated in FIG. 4, the protruding surface 13a2 may protrude from the flat surface 13al in a smooth curved surface shape in YZ cross-sectional view. Accordingly, the flat surface 10a1 and the protruding surface 10a2 may be formed as a surface in which the top surfaces and the extended surfaces thereof of the support pins 11 and the top surfaces and the extended surfaces thereof of the support pins 12 smoothly continue in the Z direction. That is, the protruding surface 10a2 may protrude while forming a surface smoothly continuing from the flat surface 10a1. This enables the adsorption stage 10 to adsorb the bonded body CB while suppressing stress concentration on the adsorption surface 10a including the flat surface 10a1 and the protruding surface 10a2, which smoothly continue at least in the Z direction.

As illustrated in FIG. 5, the protruding surface 13a2 may have a substantially circular shape in XY plan view. Accordingly, the support pins 11 and the support pins 12 may be arranged in the XY direction at substantially constant X-direction pitches P_{X} and Y-direction pitches P_{Y}. Accordingly, the flat surface 10a1 and the protruding surface 10a2 may be formed as a surface in which the top surfaces and the extended surfaces thereof of the support pins 11 and the top surfaces and the extended surfaces thereof of the support pins 12 smoothly continue in the XY direction. That is, the protruding surface 10a2 may protrude while forming a surface smoothly continuing from the flat surface 10a1. This enables the adsorption stage 10 to adsorb the bonded body CB while suppressing stress concentration on the adsorption surface 10a including the flat surface 10a1 and the protruding surface 10a2, which smoothly continue at least in the XY direction.

The stage base 13 further includes a vacuum hole 132, multiple lift pin holes 134, and multiple cylinders 135.

The vacuum hole 132 is disposed in the main body portion 131 in the region RG1. The vacuum hole 132 can be disposed at any position where the vacuum hole 132 does not interfere with the lift pin holes 134 in the region RG1 in XY plan view. The vacuum hole 132 may penetrate the stage base 13 to extend from the main surface 13a to the bottom surface 13b in the region RG1. The vacuum hole 132 communicates with vacuum piping 53. The vacuum hole 132 can be evacuated. Not one vacuum hole 132 in FIGS. 1 to 3 but multiple vacuum holes 132 may be arranged in the region RG1.

The multiple lift pin holes 134 are arranged in the region RG1. The lift pin holes 134 may penetrate the stage base 13 to extend from the main surface 13a to the bottom surface 13b in the region RG1.

The multiple cylinders 135 are arranged at positions corresponding to the positions of the lift pin holes 134 in the region RG1, and annularly surrounds the lift pin holes 134 from the outside in the XY direction. Each of the cylinders 135 may have the Z height equal to the Z height h11 of each of the support pins 11.

The support member 14 is disposed on the −Z side of the stage base 13. The support member 14 rotatably supports the stage base 13 from the −Z side. The support member 14 can be rotated about a Z axis by the driver 30.

The multiple lift pins 15 correspond to the multiple lift pin holes 134. Each of the lift pins 15 is inserted into a corresponding lift pin hole 134. The lift pins 15 can lift the bonded body CB up and down in the Z direction with respect to the adsorption surface 10a while supporting the bonded body CB.

The multiple frames 16 correspond to the multiple lift pins 15. Each of the frames 16 connects a corresponding lift pin 15 to the support member 14.

Under the control of the controller 60, the driver 30 can drive to lift the adsorption stage 10 and the bonded body CB up and down in the Z direction, and can rotationally drive the adsorption stage 10 and the bonded body CB about the Z axis. The driver 30 includes an actuator 31 and a shaft 32. The actuator 31 holds the shaft 32 such that the shaft 32 can be driven. The shaft 32 has an axis along the Z direction, and extends in the axial direction. The actuator 31 raises the shaft 32 in the Z direction while rotating the shaft 32 about the axis under the control of the controller 60.

The actuator 31 may include a rotary motor and a linear motor. The actuator 31 may rotate the shaft 32 about the axis by using the rotary motor. The actuator 31 may raise the shaft 32 in the Z direction by using the linear motor. The actuator 31 may include two rotary motors and a cam mechanism. The actuator 31 may rotate the shaft 32 about the axis by using the first rotary motor. The actuator 31 may raise the shaft 32 in the Z direction by a translational movement obtained by converting a rotational movement of the second motor into the translational movement by using the cam mechanism.

The shaft 32 is disposed between the actuator 31 and the support member 14. The shaft 32 has one end held by the actuator 31 and the other end coupled to the support member 14. A rotational motion of the shaft 32 about the axis can be transmitted as a rotational motion of the support member 14. The rotational motion of the support member 14 can be transmitted as rotational motions of the adsorption stage 10 and the bonded body CB via the frames 16 and the lift pins 15.

The laser module 20 is separately disposed on the +Z side of the adsorption stage 10. The laser module 20 includes a light source 21, an optical system 22, and a housing 23. The light source 21 and the optical system 22 are housed in the housing 23. The housing 23 has an opening on the −Z side. The light source 21 can generate a laser beam, and apply the laser beam to the bonded body CB through the optical system 22 and the opening of the housing 23 under the control of the controller 60. The optical system 22 may be, for example, a galvano optical system. The optical system 22 can finely adjust an XY application position of a laser beam to the bonded body CB under the control of the controller 60.

The driver 40 can move the adsorption stage 10 in the XY direction under the control of the controller 60. This enables the driver 40 to relatively move the laser module 20 to the adsorption stage 10 in the XY direction. The driver 40 holds the stage base 13. The driver 40 can adjust the XY application position of a laser beam to the bonded body CB by moving the stage base 13 in the XY direction under the control of the controller 60.

As indicated by an arrow of a two-dot chain line in FIG. 3, the driver 40 may gradually and relatively move the XY application position of a laser beam from an XY position on the outer peripheral side of the adsorption surface 10a to an XY position on the center side. In this case, a laser beam may be applied from the light source 21 to the bonded body CB through the optical system 22 with a predetermined period. This enables the light source 21 to sequentially apply a laser beam to the region RG1 and the region RG2.

The exhaust device 50 can evacuate the space between the bonded body CB and the stage base 13 to form a reduced-pressure atmosphere between the bonded body CB and the stage base 13. The exhaust device 50 includes a vacuum pump 51, an exhaust pipe 52, and an exhaust pipe 53. The exhaust pipe 52 causes the vacuum pump 51 and the exhaust pipe 53 to communicate with each other. The exhaust pipe 52 may penetrate the support member 14. The exhaust pipe 53 causes the exhaust pipe 52 and the vacuum hole 132 to communicate with each other. The exhaust pipe 53 may extend from an XY position near the center to an XY position of the vacuum hole 132 along the bottom surface 10b of the adsorption stage 10. The exhaust device 50 forms the reduced-pressure atmosphere between the bonded body CB and the stage base 13 under the control of the controller 60, whereby the adsorption stage 10 can adsorb the bonded body CB to the adsorption surface 10a in vacuum.

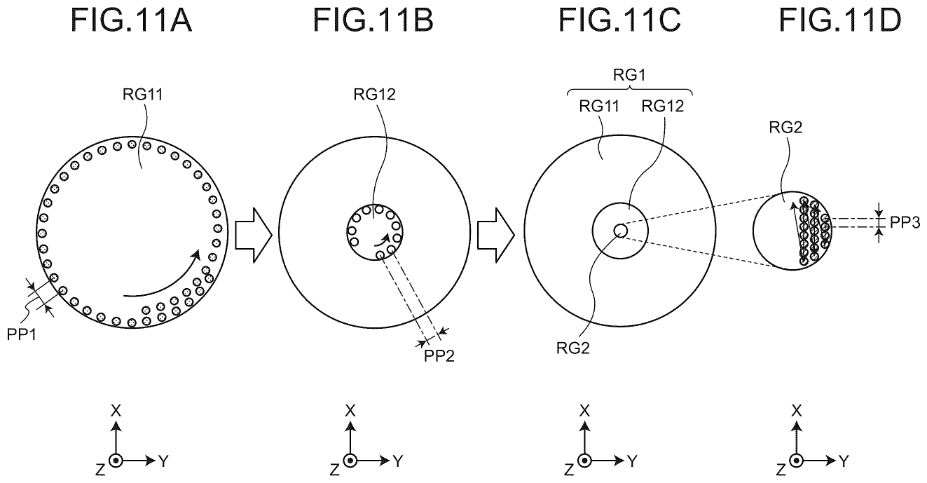

For example, when the bonded body CB is carried to the +Z side of the adsorption stage 10 and placed on the adsorption surface 10a by a conveyance device (not illustrated) or the like, the controller 60 controls the vacuum device 50 to adsorb the bonded body CB to the adsorption surface 10a. In this case, the adsorption stage 10 adsorbs the bonded body CB to the adsorption surface 10a such that the protruding surface 10a2 of the adsorption surface 10a protrudes from the flat surface 10a1 toward the +Z side (see FIG. 2). The controller 60 may gradually and relatively move the housing 23 from the XY position on the outer peripheral side of the adsorption surface 10a to the XY position on the center side with the driver 40 while rotating the adsorption stage 10 and the bonded body CB about the Z axis with the driver 30. A laser beam may be applied from the light source 21 to the bonded body CB through the optical system 22 with a predetermined period. When the housing 23 reaches an XY position in the region RG2 from an XY position in the region RG1, the controller 60 may control the optical system 22 to reciprocate the XY application position of a laser beam in the XY direction in the region RG2. This enables the light source 21 to periodically apply a laser beam while sequentially passing through the region RG1 and the region RG2 along a predetermined track (see FIGS. 11A to 11D).

As described above, in the adsorption stage 10 of the substrate peeling device 1 according to the first embodiment, the main surface 13a of the stage base 13 has the flat surface 13a1 in the region RG1, and has the protruding surface 13a2 protruding from the flat surface 13a1 to the +Z side in the region RG2. The multiple support pins 11 are arranged on the flat surface 13a1. The multiple support pins 12 are arranged on the protruding surface 13a2. The Z height h11 of each of the support pins 11 and the Z height h12 of each of the support pins 12 are equal to each other. The top surfaces and extended surfaces thereof of the multiple support pins 11 form the flat surface 10a1 in the region RG1. The top surfaces and extended surfaces thereof of the multiple support pins 12 form the protruding surface 10a2 in the region RG2. Accordingly, the adsorption surface 10a of the adsorption stage 10 has the flat surface 10a1 in the region RG1, and has the protruding surface 10a2 protruding from the flat surface 10a1 to the +Z side in the region RG2. This enables compression stress headed from the adsorption stage 10 toward the bonded body CB near the region RG2 to selectively act in a situation where tensile stress headed from the bonded body CB toward the adsorption stage 10 acts on the adsorption surface 10a at the time when the bonded body CB is adsorbed. As a result, the adsorption stage 10 can have weaker power of adsorbing the bonded body CB in the region RG2 than in the region RG1. As a result, when a laser beam is periodically applied while sequentially passing through the region RG1 and the region RG2 along a predetermined track and the substrate peeling device 1 performs laser peeling, stress between the substrates SB1 and SB2 can be relaxed at the time when peeling is performed in the region RG2, a gouge and the like of the substrates SB can be suppressed, and one of the substrates SB1 and SB2 of the bonded body CB can be appropriately peeled off the other.

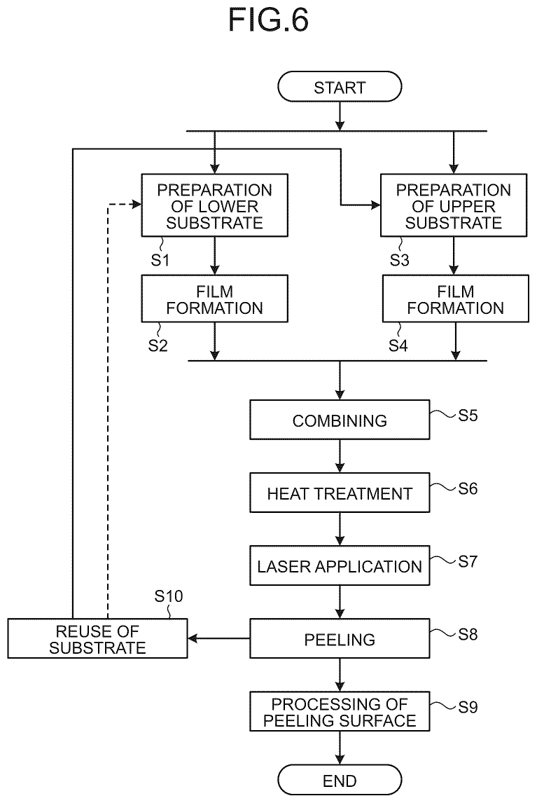

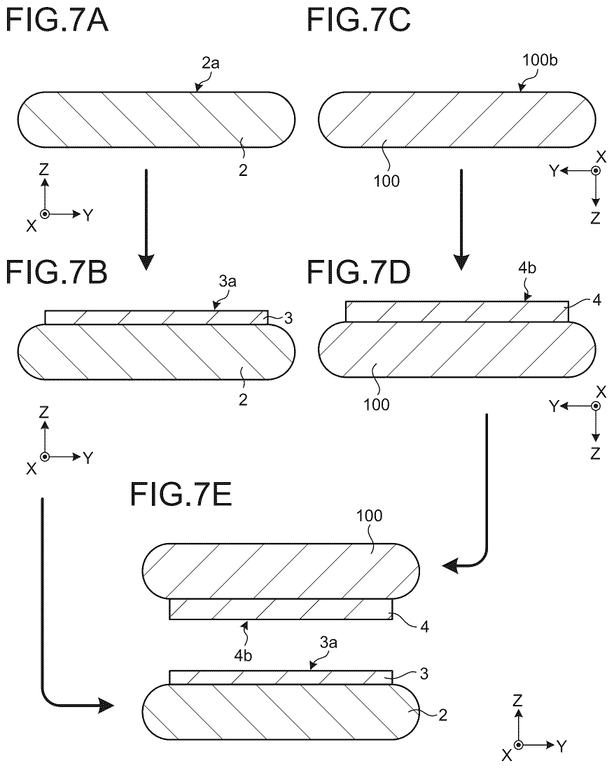

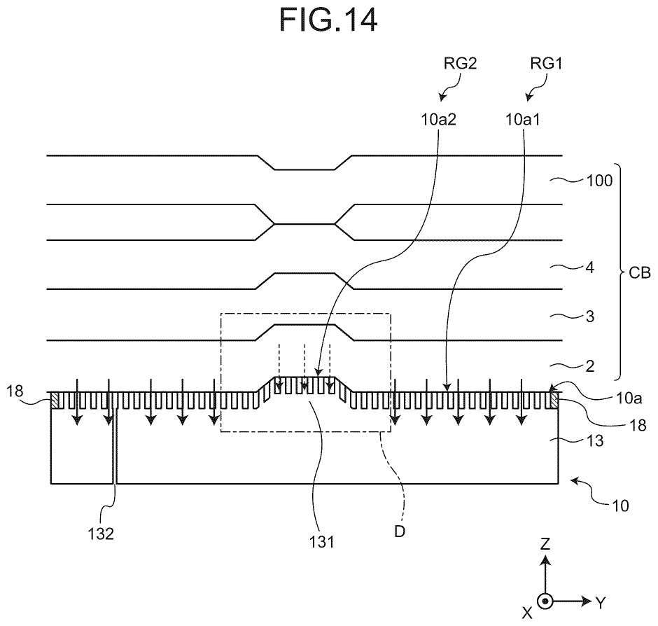

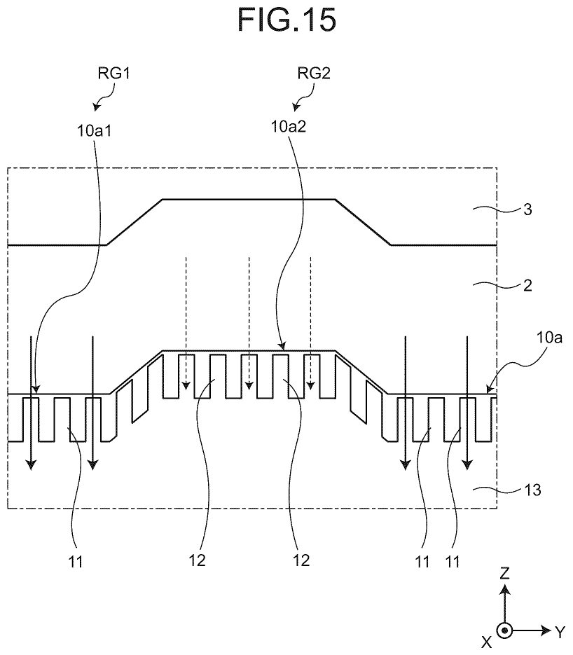

Note that the substrate peeling device 1 may be applied to a method of manufacturing a semiconductor device 300 as illustrated in FIGS. 6 to 17. FIG. 6 is a flowchart illustrating the method of manufacturing the semiconductor device 300 in a variation of the first embodiment. FIGS. 7A to 7E, 8A, 8B, 9A, 9B, 10, 12A to 12C, 13A to 13C, 16A to 16E, and 17 are YZ cross-sectional views illustrating the method of manufacturing the semiconductor device 300 in the variation of the first embodiment. FIGS. 11A to 11D are XY plan views illustrating the method of manufacturing the semiconductor device 300 in the variation of the first embodiment. FIG. 14 is a YZ cross-sectional view illustrating stress relaxation in the variation of the first embodiment. FIG. 15 is a YZ enlarged cross-sectional view illustrating the stress relaxation in the variation of the first embodiment, and corresponds to a YZ cross section obtained by enlarging a portion D in FIG. 14.

In the method of manufacturing the semiconductor device 300, as illustrated in FIG. 6, processing (S1 and S2) for a lower substrate and processing (S3 and S4) for an upper substrate are performed in parallel, for example. The lower substrate is one of two substrates to be bonded, and is disposed on the −Z side at the time of the bonding. The upper substrate is the other of the two substrates to be bonded, and is disposed on the +Z side at the time of the bonding.

In preparation of the lower substrate (S1), a substrate (lower substrate) 2 is prepared as illustrated in FIG. 7A. The substrate 2 may be made of a material containing a semiconductor substantially free of impurities (e.g., silicon) as a main component.

In film formation (S2), as illustrated in FIG. 7B, a predetermined device structure is formed on the side of a main surface 2a (+Z side) of the substrate 2.

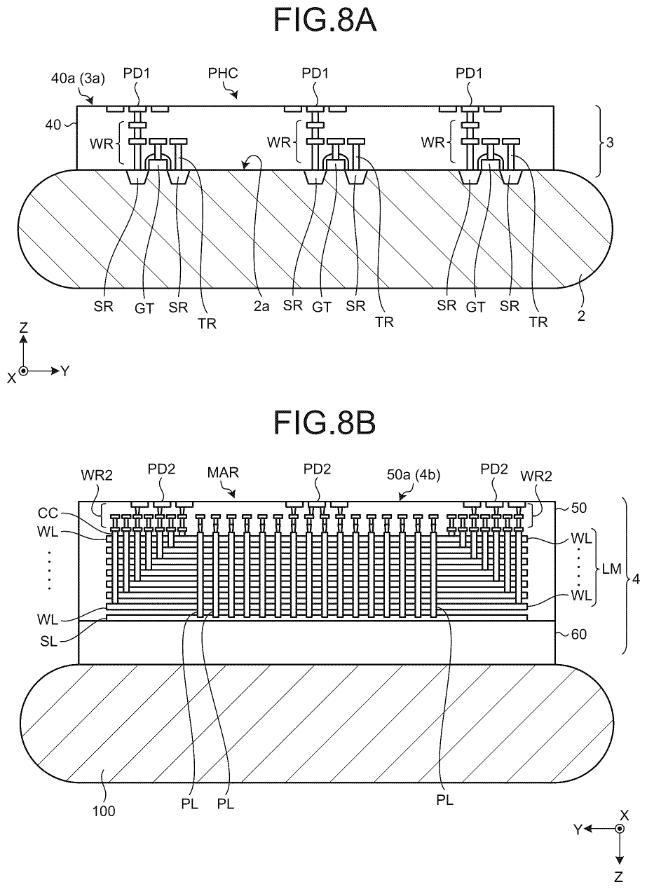

For example, a peripheral circuit structure PHC as illustrated in FIG. 8A may be formed. Impurities are introduced into the vicinity of the main surface 2a on the +Z side of the substrate 2 to form a semiconductor region SR. A conductive pattern GT is formed on the main surface 2a of the substrate 2. This causes multiple transistors TR each including the semiconductor region SR and the conductive pattern GT to be formed. The peripheral circuit structure PHC including the multiple transistors TR functions as a peripheral circuit for a memory cell array structure MAR to be described later.

After the predetermined device structure is formed, a film 3 is formed by a CVD method or the like. For example, an interlayer insulating film 40 may be made of a material containing an insulator as a main component, or may be made of a material containing semiconductor oxide (e.g., silicon oxide) as a main component. Furthermore, a wiring structure WR to be electrically connected the transistors TR is formed by making a hole to embed a conductor in the interlayer insulating film 40 and forming a conductive pattern with deposition of the interlayer insulating film 40. An electrode PD1 to be electrically connected to the wiring structure WR is formed by plating or the like on a main surface 40a of the interlayer insulating film 40 on the +Z side. In FIG. 7B and the subsequent drawings, for the sake of simplicity, a film including the conductive pattern GT, the wiring structure WR, the electrode PD1, and the interlayer insulating film 40 is illustrated and described as the film 3.

Furthermore, since the interlayer insulating film 40 occupies most of the film 3 in terms of volume, the film 3 is treated as a film that may be formed of a material containing semiconductor oxide (e.g., silicon oxide) as a main component. Note that the device structure in FIG. 8A is an example, and the present invention is not limited to the device structure.

In preparation of the upper substrate (S3), a substrate (upper substrate) 100 is prepared as illustrated in FIG. 7C. The substrate 100 may be made of a material containing a semiconductor substantially free of impurities (e.g., silicon) as a main component.

In film formation (S4), as illustrated in FIG. 7D, a film 4 covering a main surface 100b of the substrate 100 is formed by a CVD method or the like.

For example, the film 4 including the memory cell array structure MAR as illustrated in FIG. 8B may be formed. A conductive layer SL is formed by depositing an insulating film 60 covering the main surface 100b of the substrate 100, depositing a conductive layer, and patterning the conductive layer. The insulating film 60 can be made of an insulator such as silicon oxide. The conductive layer SL can be made of a semiconductor imparted with conductivity, such as polysilicon containing impurities. Thereafter, an insulating layer and a sacrificial layer (not illustrated) are alternately deposited multiple times on the +Z side of the conductive layer SL to form a stacked body LM. The insulating layer can be made of an insulator such as silicon oxide. The sacrificial layer can be made of an insulator capable of securing etching selectivity with the insulating layer such as silicon nitride. Each insulating layer and each sacrificial layer can be deposited with a substantially similar film thickness.

A resist pattern is formed on the −Z side of the stacked body. The resist pattern extends in the Y direction, and is linearly opened. Anisotropic etching such as a reactive ion etching (RIE) method is performed by using the resist pattern as a mask to form a groove penetrating the stacked body LM in a YZ direction. Then, a division film (not illustrated) is embedded in the groove. The division film can be made of a material containing an insulator (e.g., silicon oxide) as a main component. The division film extends in the YZ direction on a −X side of the stacked body LM. The division film divides the stacked body LM from another stacked body LM on the −X side. In each stacked body LM, an insulating layer and a sacrificial layer are alternately stacked multiple times. Each stacked body LM has a substantially rectangular shape with the Y direction as a longitudinal direction in XY plan view.

A resist pattern opened at a memory hole formation position is formed on the −Z side of each stacked body. Anisotropic etching such as an RIE method is performed by using the resist pattern as a mask to form a memory hole that penetrates the stacked body LM and reaches the conductive layer SL.

A block insulating film, a charge storage film, and a tunnel insulating film are sequentially deposited on the side surface and the bottom surface of the memory hole. The block insulating film can be made of an insulator such as silicon oxide. A portion of the bottom surface of the memory hole in the tunnel insulating film is selectively removed.

A semiconductor film is deposited on the side surface and the bottom surface of the memory hole. The semiconductor film can be made of a material containing a semiconductor (e.g., polysilicon) as a main component. Then, a core member is embedded in the memory hole. The core member can be made of an insulator such as silicon oxide. This causes multiple columnar bodies PL each penetrating the stacked body LM in the Z direction to be formed. The multiple columnar bodies PL are formed so as to be arranged in the XY direction.

The sacrificial layer of the stacked body LM is removed. The block insulating film is formed on an exposed surface of a void formed by the removal. The block insulating film can be made of an insulator such as aluminum oxide. A conductive layer WL is further embedded in the void. The conductive layer WL can be made of a material containing a conductor (e.g., metal such as tungsten) as a main component. This causes the stacked body LM in which a conductive layer WL and an insulating layer are alternately and repeatedly stacked to be formed. Memory cells are formed at positions where the conductive layers WL intersect semiconductor films of the columnar bodies PL. That is, the memory cell array structure MAR in which multiple memory cells are three-dimensionally arranged is formed.

Furthermore, an interlayer insulating film 50 covering the stacked body LM is further formed. A staircase structure in which the conductive layers WL are drawn in a staircase pattern on both sides of the stacked body LM in the Y direction is formed by formation of a resist pattern, slimming, and etching processing. A conductive plug CC to be electrically connected to each of the conductive layers WL is formed by, for example, forming a hole in the interlayer insulating film 50 and embedding a conductor. Furthermore, a wiring structure WR2 to be electrically connected the conductive plug CC is formed by making a hole to embed a conductor in the interlayer insulating film 50 and forming a conductive pattern with deposition of the interlayer insulating film 50. An electrode PD2 to be electrically connected to the wiring structure WR2 is formed by plating or the like on a main surface 50a of the interlayer insulating film 50 on the −Z side. In FIG. 7D and the subsequent drawings, for the sake of simplicity, a film including the memory cell array structure MAR, the conductive plug CC, the wiring structure WR2, the electrode PD2, and the interlayer insulating films 50 and 60 is illustrated and described as the film 4. Furthermore, the film 4 is treated as being mainly made of a material of the interlayer insulating film 60. Note that the device structure in FIG. 8B is an example, and the present invention is not limited to the device structure. Furthermore, although FIG. 8B illustrates one memory cell array structure MAR, multiple memory cell array structures MAR may be provided.

The film 4 can be made of any material having a higher rate of absorption of infrared light than the substrate 100. The film 4 may be made of any material having a larger rate of absorption of a laser wavelength (e.g., 9200 nm or more and 10800 nm or less) suitable for the film 4 to function as a laser absorbing layer than the substrate 100. The film 4 may be made of a material containing an insulator as a main component, or may be made of a material containing semiconductor oxide (e.g., silicon oxide) as a main component.

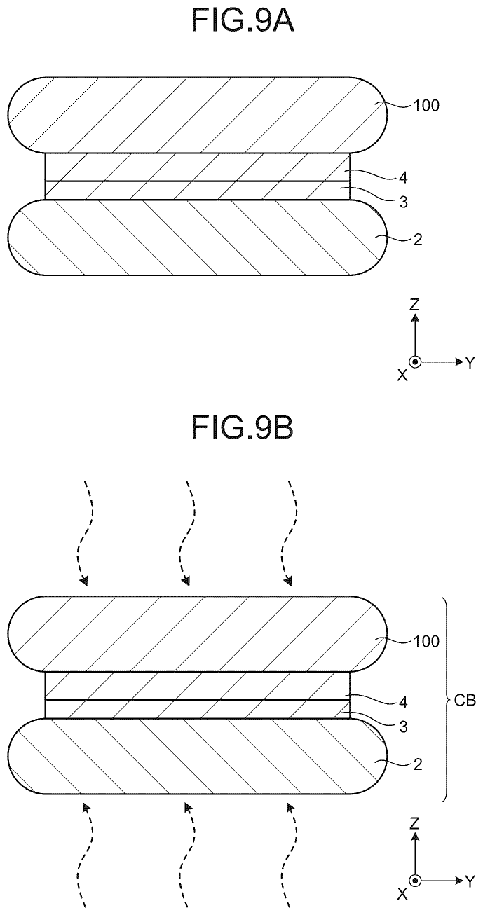

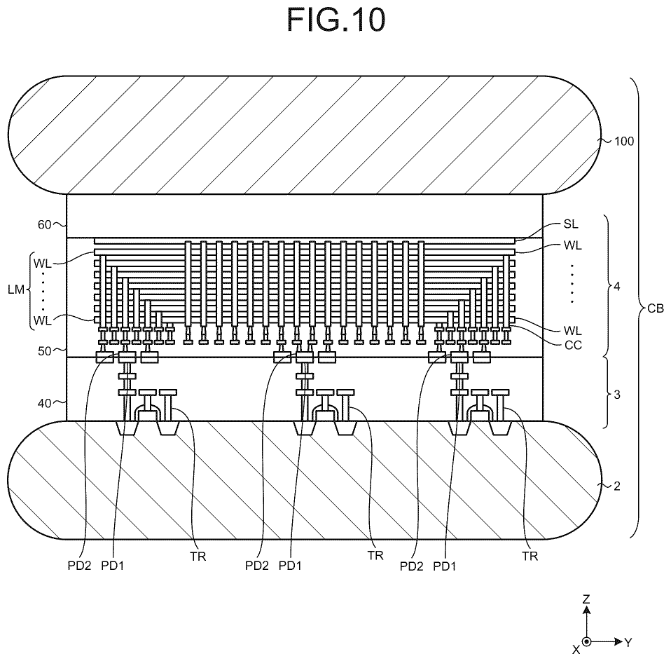

As illustrated in FIG. 6, when both the processing (S1 and S2) for the lower substrate and the processing (S3 to S4) for the upper substrate are completed, the upper substrate and the lower substrate are bonded (S5). A main surface 3a (see FIG. 7B) of the film 3 on the +Z side and a main surface 4b (see FIG. 7D) of the film 4 on the −Z side are activated by plasma application and the like. As illustrated in FIG. 7E, the substrate 2 and the substrate 100 are arranged so as to face each other in the Z direction such that the main surface 3a and the main surface 4b face each other. As illustrated in FIGS. 7E, 9A, and 10, an XY position of the substrate 2 and an XY position of the substrate 100 are aligned such that an XY position of the electrode PD1 on the main surface 3a corresponds to an XY position of the electrode PD2 on the main surface 4b. As illustrated in FIGS. 9A and 10, the substrate 2 and the substrate 100 are brought close to each other in the Z direction. The main surface 3a on the side of the substrate 2 and the main surface 4b on the side of the substrate 100 are bonded by direct bonding. In this case, atoms of the main surface 3a and atoms of the main surface 4b are coupled by hydrogen coupling or the like. The substrate 2 and the substrate 100 are temporarily bonded.

Thus, as illustrated in FIG. 6, heat treatment (annealing) is performed at a relatively low temperature (S6). In the heat treatment (annealing), the substrate 2 and the substrate 100 are entirely heated as indicated by dotted arrows in FIG. 9B. In the heat treatment, for example, each of the substrate 2 and the substrate 100 is heated to a relatively low temperature (i.e., acceptable temperature of device structure, for example, approximately 200° C.) for a predetermined time. In this case, atoms of the main surface 3a and atoms of the main surface 4b are coupled by covalent coupling or the like by water molecules escaping from an interface. The substrate 2 and the substrate 100 are finally bonded. This causes the bonded body CB of the substrate 2 and the substrate 100 to be formed. In this case, the electrode PD1 and the electrode PD2 can be bonded by direct bonding. The peripheral circuit structure PHC and the memory cell array structure MAR can be electrically connected.

When S6 in FIG. 6 is completed, the conveyance device (not illustrated) or the like carries the bonded body CB to the +Z side of the adsorption stage 10 of the substrate peeling device 1 (see FIG. 1), and places the bonded body CB on the adsorption surface 10a. The substrate peeling device 1 controls the vacuum device 50 to adsorb the bonded body CB to the adsorption surface 10a. In this case, the adsorption stage 10 adsorbs the bonded body CB to the adsorption surface 10a such that the adsorption surface 10a has the flat surface 10a1 in the region RG1 and has the protruding surface 10a2 in the region RG2 (see FIG. 2). In this state, the substrate peeling device 1 applies the laser beam 200 from the side of the substrate 100 to the bonded body CB such that the focal point is located in the vicinity of the film 4 (S7).

Note that, in the embodiment, one application of the laser beam 200 includes the first application of the laser beam 200 to the Nth application of the laser beam 200 to the entire substrate. N is any integer of two or more.

The substrate peeling device 1 applies a laser beam 200 in which the film 4 serving as a laser absorbing layer has a light absorption rate in a larger wavelength band (e.g., preferably 1117 nm or more and more preferably near 9300 nm or near 10600 nm in case where laser absorbing layer is silicon oxide film) than the substrate 100. A pulse laser is used as the laser beam 200. An infrared laser may be used as the laser beam 200. A carbon dioxide laser (CO₂ laser) may be used as the laser beam 200. The laser beam 200 is absorbed depending on the absorption coefficient and the thickness of a substrate or a film. In the structure, the laser is absorbed most in the film 4 serving as a laser absorbing layer.

In this case, the substrate peeling device 1 applies the laser beam 200 such that multiple application portions are two-dimensionally distributed in the film 4 as illustrated in FIGS. 11A to 11D. The substrate peeling device 1 applies the laser beam 200 such that the multiple application portions are separated from each other in an XY plane direction. The substrate peeling device 1 applies the laser beam 200 while adjusting an application interval to be suitable for peeling in consideration of an influence of heat storage due to local heat generation in the film 4.

The substrate peeling device 1 may apply the laser beam 200 while changing a condition in multiple stages. As illustrated in FIG. 11C, the region RG1 in the adsorption stage 10 is divided into an outer region RG11 and an inner region RG12. FIGS. 11A to 11D illustrate a case where the substrate peeling device 1 applies the laser beam 200 while changing a condition in three stages of the region RG11→ the region RG12→ the region RG2. FIG. 11D is an XY enlarged plan view illustrating the enlarged region RG2 in FIG. 11C.

In application of a laser to the region RG11 in FIG. 11A, the substrate peeling device 1 relatively moves the laser module 20 from the outer periphery gradually to the inner peripheral side in the adsorption stage 10 while rotating the adsorption stage 10 at a gradually increasing rotation speed. This causes the substrate peeling device 1 to move the portions of application of the laser beam 200 along a spiral track headed from the outer periphery gradually to the inner periphery in the region RG11. The laser beam may have a pulse frequency of a fixed value of, for example, 10 to 100 kHz. The application portions may have a pitch PP1 of 15 μm. The application portions may have a radius of 12 mm or less. The rotation speed of the adsorption stage 10 may be adjusted so as to gradually increase in a range of 0.80 to 47.8 rotations/second.

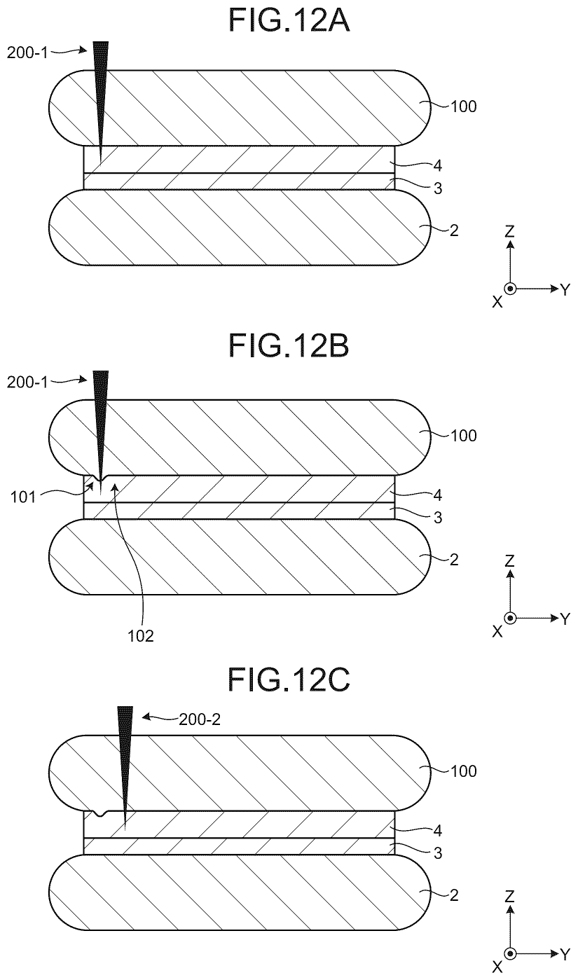

For example, as illustrated in FIG. 12A, the substrate peeling device 1 determines an XY plane position where a laser beam 200-1 of the first application is to be applied, and adjusts the focal point of the laser beam 200-1 to be located in the film 4. The XY plane position where application is to be performed may be a start position of the spiral track (see FIG. 11A). The film 4 has a rate of absorption of the laser beam 200-1 larger than a rate of absorption of the laser beam 200-1 of the substrate 100. This causes the laser beam 200-1 applied to the film 4 through the substrate 100 to be efficiently absorbed at an application portion in the film 4, and causes local heat generation (local heating) in the film 4 at the XY plane position.

As illustrated in FIG. 12B, the locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms a protrusion 101 in which the substrate 100 protrudes to the side of the film 4. A recess 102 is formed around the protrusion 101. This generates compression stress at the interface between a tip of the protrusion 101 and the film 4 while generating tensile stress at the interface between the bottom surface of the recess 102 and the film 4. The film 4 and the substrate 100 can be partially peeled around the XY plane position.

As illustrated in FIG. 12C, the substrate peeling device 1 determines an XY plane position where a laser beam 200-2 of the second application is to be applied to a position as a result of the XY plane position in FIG. 12A being shifted in the XY plane direction, and adjusts the focal point of the laser beam 200-2 to be located in the film 4. The position shifted from the XY plane position in FIG. 12A in the XY plane direction may be a position shifted from the start position along the spiral track (see FIG. 11A). The film 4 has a rate of absorption of the laser beam 200-2 larger than a rate of absorption of the laser beam 200-2 of the substrate 100. This causes the laser beam 200-2 applied to the film 4 through the substrate 100 to be efficiently absorbed at an application portion in the film 4, and causes local heat generation (local heating) in the film 4 at the XY plane position.

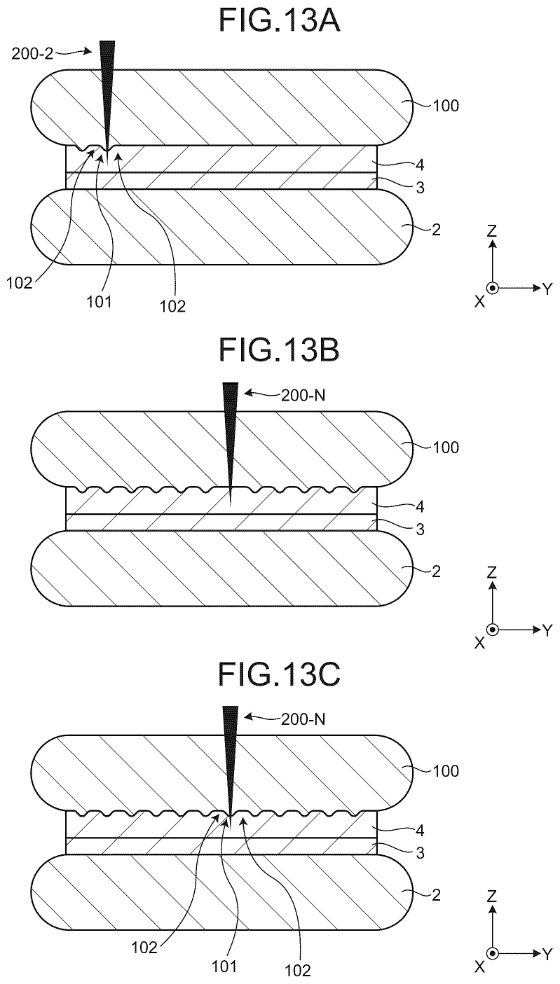

As illustrated in FIG. 13A, the locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms the protrusion 101 in which the substrate 100 protrudes to the side of the film 4. The recess 102 is formed around the protrusion 101. This generates compression stress at the interface between a tip of the protrusion 101 and the film 4 while generating tensile stress at the interface between the bottom surface of the recess 102 and the film 4. The film 4 and the substrate 100 can be partially peeled around the XY plane position.

Although not illustrated, the substrate peeling device 1 determines an XY plane position where a laser beam 200-k of the kth application immediately before arrival at the region RG12 is to be applied to a position shifted from the XY plane position of the (k−1)th application in the XY plane direction, and adjusts the focal point of the laser beam 200-k to be located in the film 4. Here, k is any integer larger than two and less than N. The position shifted from the XY plane position of the (k−1)th application in the XY plane direction may be a position shifted from the position of the (k−1)th application along the spiral track (see FIG. 11A). The film 4 has a rate of absorption of the laser beam 200-k larger than a rate of absorption of the laser beam 200-k of the substrate 100. This causes the laser beam 200-k applied to the film 4 through the substrate 100 to be efficiently absorbed at an application portion in the film 4, and causes local heat generation (local heating) in the film 4 at the XY plane position.

The locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms the protrusion 101 in which the substrate 100 protrudes to the side of the film 4. The recess 102 is formed around the protrusion 101. This generates compression stress at the interface between a tip of the protrusion 101 and the film 4 while generating tensile stress at the interface between the bottom surface of the recess 102 and the film 4. The film 4 and the substrate 100 can be partially peeled around the XY plane position.

In application of a laser to the region RG12 in FIG. 11B, the substrate peeling device 1 relatively moves the laser module 20 from the outer periphery gradually to the inner peripheral side in the adsorption stage 10 while rotating the adsorption stage 10 at a fixed rotation speed. This causes the substrate peeling device 1 to move the portions of application of the laser beam 200 along a spiral track headed from the outer periphery gradually to the inner periphery in the region RG12. The laser beam may have a gradually increasing pulse frequency in a range of, for example, 10 to 100 kHz. The application portions may have a pitch PP2 smaller than PP1. The application portions may have a gradually decreasing radius in a range of 12 to 2.5 mm. The adsorption stage 10 may have a fixed rotation speed of 47.8 rotations/second.

Although not illustrated, the substrate peeling device 1 determines an XY plane position where a laser beam 200-(k+1) of the (k+1)th application immediately after arrival at the region RG12 is to be applied to a position shifted from the XY plane position of the kth application in the XY plane direction, and adjusts the focal point of the laser beam 200-(k+1) to be located in the film 4. The position shifted from the XY plane position of the kth application in the XY plane direction may be a position shifted from the position of the kth application along the spiral track (see FIG. 11A). The film 4 has a rate of absorption of a laser beam 200-(k+1) larger than a rate of absorption of the laser beam 200-(k+1) of the substrate 100. This causes the laser beam 200-(k+1) applied to the film 4 through the substrate 100 to be efficiently absorbed at an application portion in the film 4, and causes local heat generation (local heating) in the film 4 at the XY plane position.

The locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms the protrusion 101 in which the substrate 100 protrudes to the side of the film 4. The recess 102 is formed around the protrusion 101. This generates compression stress at the interface between a tip of the protrusion 101 and the film 4 while generating tensile stress at the interface between the bottom surface of the recess 102 and the film 4. The film 4 and the substrate 100 can be partially peeled around the XY plane position.

Although not illustrated, the substrate peeling device 1 determines an XY plane position where a laser beam 200-j of the jth application immediately before arrival at the region RG2 is to be applied to a position shifted from the XY plane position of the (j−1)th application in the XY plane direction, and adjusts the focal point of the laser beam 200-j to be located in the film 4. Here, j is any integer exceeding k and less than N. The position shifted from the XY plane position of the (j−1)th application in the XY plane direction may be a position shifted from the position of the (j−1)th application along the spiral track (see FIG. 11B). The film 4 has a rate of absorption of the laser beam 200-j larger than a rate of absorption of the laser beam 200-j of the substrate 100. This causes the laser beam 200-j applied to the film 4 through the substrate 100 to be efficiently absorbed at an application portion in the film 4, and causes local heat generation (local heating) in the film 4 at the XY plane position.

The locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms the protrusion 101 in which the substrate 100 protrudes to the side of the film 4. The recess 102 is formed around the protrusion 101. This generates compression stress at the interface between a tip of the protrusion 101 and the film 4 while generating tensile stress at the interface between the bottom surface of the recess 102 and the film 4. The film 4 and the substrate 100 can be partially peeled around the XY plane position.

In application of a laser to the region RG2 in FIGS. 11C and 11D, the substrate peeling device 1 controls the optical system 22 such that the XY application position of a laser beam reciprocates in the XY direction in the region RG2 with the rotation of the adsorption stage 10 being stopped. This causes the substrate peeling device 1 to move the portions of application of the laser beam 200 along a zigzag track in the region RG2. FIG. 11D illustrates an application pattern in which the XY application position of the laser beam gradually shifts in the Y direction while reciprocating in the X direction. The laser beam may have a fixed pulse frequency in a range of, for example, 10 to 100 kHz. The application portions may have a pitch PP3 smaller than PP2. The application portions may have a gradually decreasing radius in a range of 2.5 to 0.1 mm.

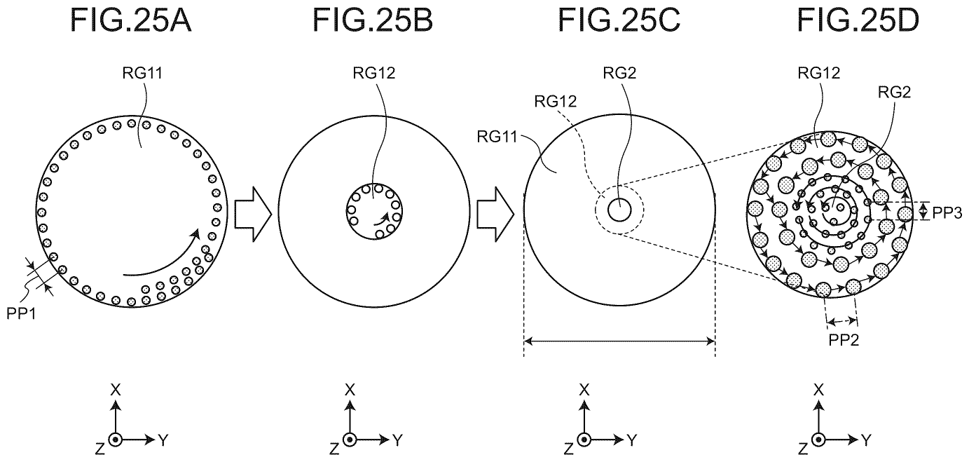

Note that, although FIG. 11D illustrates a case where the substrate peeling device 1 moves the portions of application of the laser beam 200 along the zigzag track in region RG2, the substrate peeling device 1 may move the portions of application of the laser beam 200 along the spiral track in the region RG2 (see FIG. 25A to 25D).

Although not illustrated, the substrate peeling device 1 determines an XY plane position where a laser beam 200-(j+1) of the (j+1)th application immediately after arrival at the region RG12 is to be applied to a position shifted from the XY plane position of the jth application in the XY plane direction, and adjusts the focal point of the laser beam 200-(j+1) to be located in the film 4. The position shifted from the XY plane position of the jth application in the XY plane direction may be a position shifted from the position of the jth application along the spiral track (see FIG. 11B). The film 4 has a rate of absorption of a laser beam 200-(j+1) larger than a rate of absorption of the laser beam 200-(j+1) of the substrate 100. This causes the laser beam 200-(j+1) applied to the film 4 through the substrate 100 to be efficiently absorbed at an application portion in the film 4, and causes local heat generation (local heating) in the film 4 at the XY plane position.

The locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms the protrusion 101 in which the substrate 100 protrudes to the side of the film 4. The recess 102 is formed around the protrusion 101. This generates compression stress at the interface between a tip of the protrusion 101 and the film 4 while generating tensile stress at the interface between the bottom surface of the recess 102 and the film 4. The film 4 and the substrate 100 can be partially peeled around the XY plane position.

As illustrated in FIG. 13B, the substrate peeling device 1 determines the final XY plane position where a laser beam 200-N of the Nth application is to be applied, and adjusts the focal point of the laser beam 200-N to be located in the film 4. The final XY plane position may be the final position along the zigzag track (see FIG. 11D). The film 4 has a rate of absorption of the laser beam 200-N larger than a rate of absorption of the laser beam 200-N of the substrate 100. This causes the laser beam 200-N applied to the film 4 through the substrate 100 to be efficiently absorbed at an application portion in the film 4, and causes local heat generation (local heating) in the film 4 at the final XY plane position.

As illustrated in FIG. 13C, the locally generated heat of the film 4 is transmitted to the interface between the film 4 and the substrate 100. The substrate 100 has a thermal expansion coefficient larger than that of the film 4. Therefore, the substrate 100 expands to the side of the film 4 at the final XY plane position, which forms the protrusion 101 in which the substrate 100 protrudes to the side of the film 4. The recess 102 is formed around the protrusion 101. This generates compression stress at the interface between the tip of the protrusion 101 and the film 4 while generating tensile stress at the interface between the bottom surface of the recess 102 and the film 4. The film 4 and the substrate 100 can be partially peeled around the final XY plane position.

In this case, as illustrated in FIGS. 14 and 15, the protruding surface 10a2 of the region RG2 in the adsorption stage 10 protrudes from the flat surface 10a1 of the region RG1 to the +Z side (see FIG. 2). This enables stress in a direction opposite to adsorption power to be selectively generated at the interface between the adsorption stage 10 and the bonded body CB in the region RG2, which can relax the adsorption power. That is, in the adsorption stage 10, power of adsorbing the bonded body CB in the region RG2 can be weaker than power of adsorbing the bonded body CB in the region RG1. In FIGS. 14 and 15, stress in the region RG2 is indicated by a dotted arrow, and stress in the region RG1 is indicated by a solid arrow. The dotted arrow indicates smaller stress than the solid arrow.

For example, in a state where the film 4 and the substrate 100 are partially connected to each other at a portion corresponding to the region RG2 as illustrated in FIGS. 14 and 15, tensile stress in a −Z direction caused by adsorption from the adsorption stage 10 and tensile stress in a +Z direction caused by deformation of the substrate 100 can act on the connection portion. Here, since tensile stress of the region RG2 on the adsorption surface 10a of the adsorption stage 10 is relaxed more than tensile stress of the region RG1, the connection portion between the film 4 and the substrate 100 in the vicinity of the final XY plane position can be gradually peeled. This can suppress a defect such as a gouge from being generated at the final peeling portion corresponding to the region RG2 of each of the film 4 and the substrate 100.

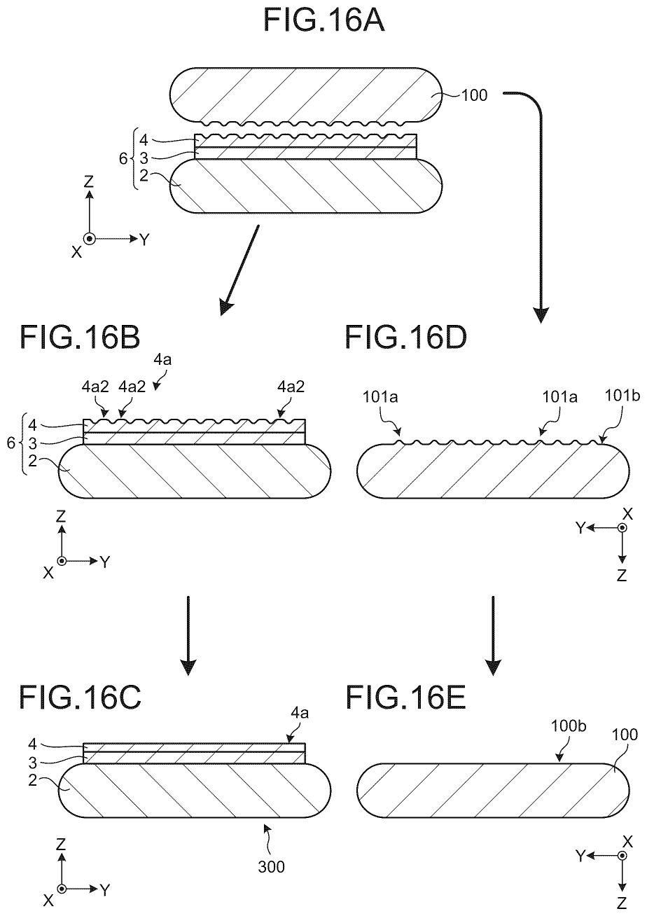

As partial peeling gradually progresses, peeling is performed at the interface between the film 4 and the substrate 100 (S9). That is, as illustrated in FIG. 16A, the substrate 100 is peeled off a stacked body 6 in which the films 3 and 4 are stacked on the substrate 2.

In consideration of the subsequent processing and the like, the peeling surface of the stacked body 6 is processed as illustrated in FIG. 6 (S9). In the stacked body 6, as illustrated in FIG. 16B, multiple protrusions 4a2 are distributed in the XY direction on a main surface 4a of the film 4 on the +Z side. The main surface 4a is polished and flattened by a CMP method and the like.

This enables the semiconductor device 300, in which the films 3 and 4 are stacked on the substrate 2 and the main surface 4a of the film 4 is flattened, to be obtained as illustrated in FIG. 16C.

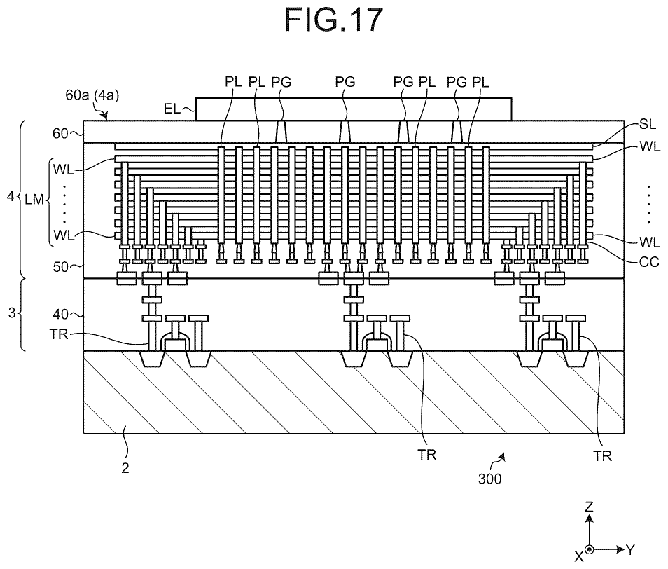

For example, as illustrated in FIG. 17, a conductive plug PG to be electrically connected to the conductive layer SL is formed by forming a hole in a main surface 60a of the interlayer insulating film 60 on the +Z side and embedding a conductor after the flattening. An electrode pattern EL to be electrically connected to the conductive plug PG is formed on the main surface 60a of the interlayer insulating film 60 by plating or the like. Furthermore, although not illustrated, an electrode pattern EL that bypasses the memory cell array structure MAR and that is to be connected to the peripheral circuit structure PHC is also formed on the main surface 60a of the interlayer insulating film 60. This enables a power supply, a signal, and the like to be supplied from the outside to the memory cell array structure MAR and the peripheral circuit structure PHC.

Note that the film 4 including the memory cell array structure MAR can be regarded as a chip region for a memory cell array. The film 3 including the peripheral circuit structure PHC and the substrate 2 can be regarded as a chip region for a peripheral circuit. A semiconductor device 1 has a structure obtained by directly bonding the chip region for a memory cell array with the chip region for a peripheral circuit. The structure is also called a CMOS directly bonded to array (CBA). In the CBA, not one but two or more chip regions for a memory cell array to be bonded to the +Z side of a chip region for a peripheral circuit may be provided.

In contrast, the peeled substrate 100 is reused as illustrated in FIG. 6 (S10). The substrate 100 may be reused as the upper substrate 100 as indicated by a solid arrow in FIG. 6.

In the substrate 100 immediately after peeling, as illustrated in FIG. 16D, multiple protrusions 101a are distributed in the XY direction on the main surface 100b on the −Z side. The main surface 100b is polished and flattened by a CMP method and the like. This enables the substrate 100 in which the main surface 100b is flattened as illustrated in FIG. 16E to be obtained. Since the main surface 100b of the substrate 100 in FIG. 16E is flattened, the substrate 100 can be easily reused as, for example, the upper substrate 100.

Note that the peeled substrate 100 may be reused as the lower substrate 2 as indicated by a dotted arrow in FIG. 6 instead of being reused as the upper substrate 100.

In this way, the substrate 100 in the bonded body CB can be appropriately peeled off the stacked body 6 in which the films 3 and 4 are stacked on the substrate 2 by applying the substrate peeling device 1 to the method of manufacturing the semiconductor device 300 in FIGS. 6 to 17.

### Second Embodiment

Next, a substrate peeling device according to a second embodiment will be described. Portions different from those of the first embodiment will be mainly described below.

Although, in the first embodiment, a structure in which the protruding surface 10a2 of the region RG2 protrudes from the flat surface 10a1 of the region RG1 to the +Z side in the adsorption stage 10 is illustrated, a structure in which recessed space SP11 of the region RG1 in an adsorption stage 410 can be selectively depressurized is illustrated in the second embodiment.

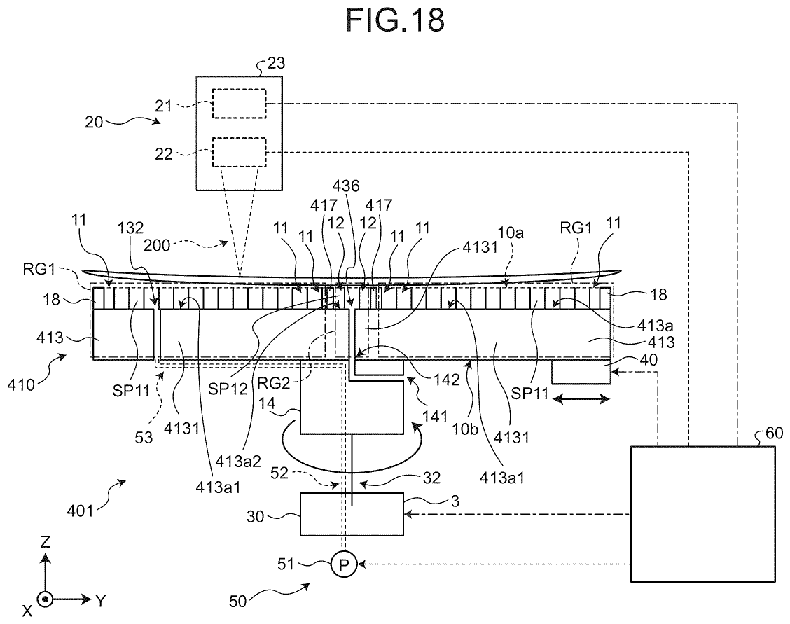

As illustrated in FIG. 18, a substrate peeling device 401 includes an adsorption stage 410 instead of the adsorption stage 10 (see FIG. 1). FIG. 18 illustrates a schematic configuration of the substrate peeling device 401.

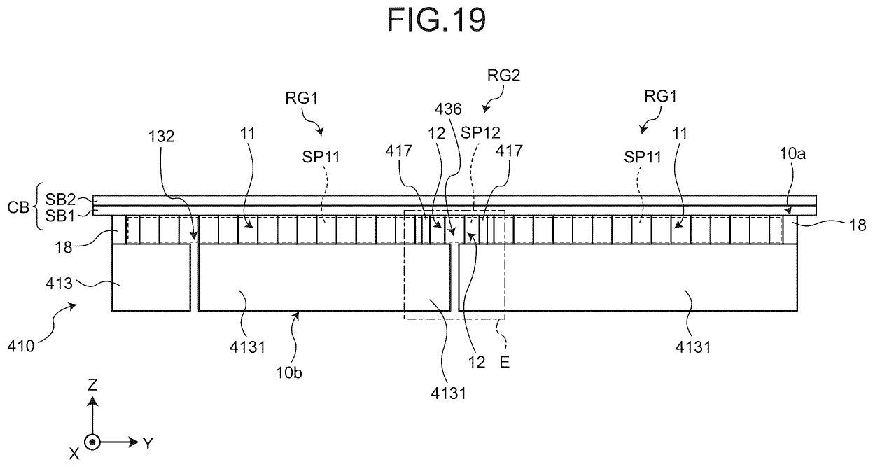

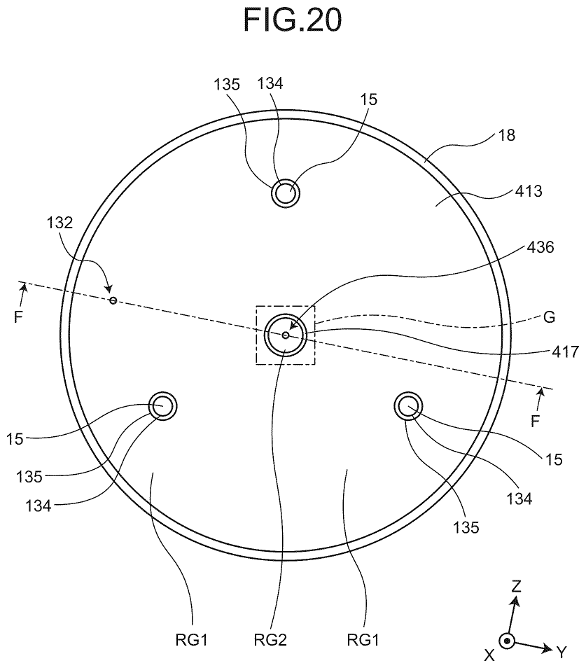

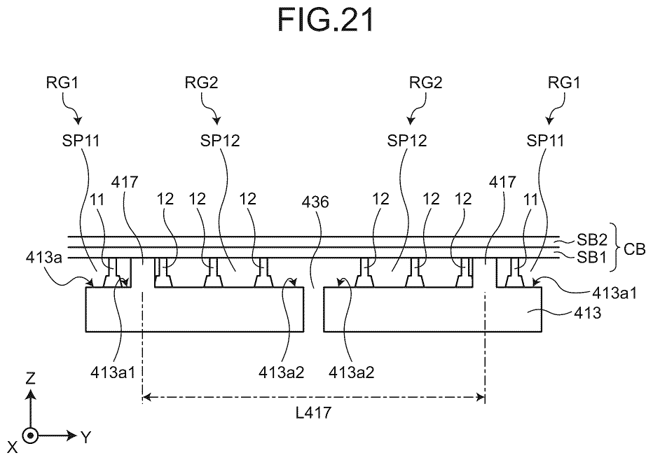

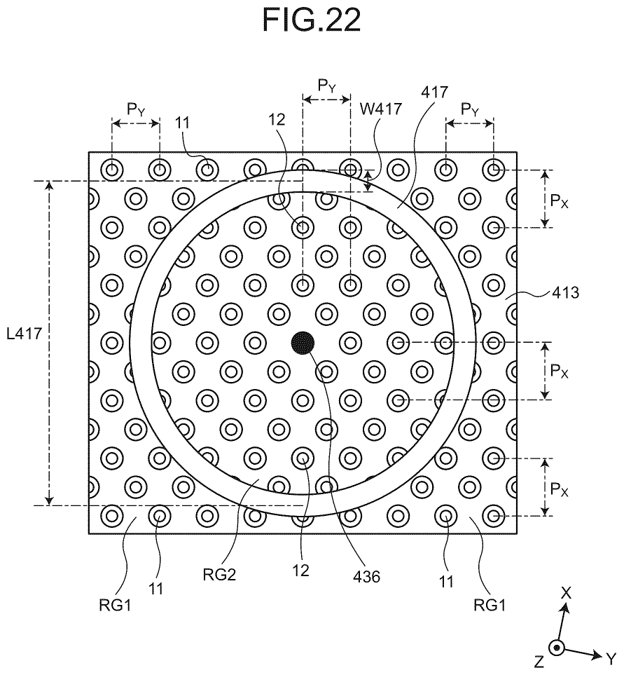

As illustrated in FIGS. 19 to 22, the adsorption stage 410 includes a stage base 413 instead of the stage base 13 (see FIGS. 2 to 5), and further includes a partition wall 417. FIG. 19 is a YZ cross-sectional view illustrating a configuration of the adsorption stage 410. FIG. 20 is an XY plan view illustrating the configuration of the adsorption stage 410. The YZ cross-sectional view of FIG. 19 corresponds to a YZ cross section taken along line F-F in FIG. 20. FIG. 21 is a YZ enlarged cross-sectional view illustrating a configuration near the center of the adsorption stage 410, and corresponds to a YZ cross-sectional view obtained by enlarging a portion E in FIG. 19. FIG. 22 is an XY enlarged plan view illustrating the configuration near the center of the adsorption stage 410, and corresponds to an XY plan view obtained by enlarging a portion G in FIG. 20.

The adsorption stage 410 can selectively depressurize the recessed space SP11 of the region RG1, and can relatively increase the pressure of recessed space SP12 of the region RG2 as compared to the pressure of the recessed space SP11 of the region RG1. This can reduce tensile stress headed from the bonded body CB toward the adsorption stage 10 in the region RG2 at the time when the bonded body CB is adsorbed as compared to tensile stress headed from the bonded body CB toward the adsorption stage 10 in the region RG1. As a result, the adsorption stage 10 can have weaker power of adsorbing the bonded body CB in the region RG2 than in the region RG1.

The stage base 413 has a main surface 413a extending flat in the XY direction in the region RG1 and the region RG2. The stage base 413 further includes a pressure adjusting hole 436 added to the stage base 13 (see FIGS. 2 to 5). The pressure adjusting hole 436 is disposed in a main body portion 4131 in the region RG2. The pressure adjusting hole 436 can be disposed at any position where the pressure adjusting hole 436 does not interfere with the partition wall 417 in the region RG2 in XY plan view.

The pressure adjusting hole 436 may extend to the bottom surface 10b through the recessed space SP11. A hole 142 and a hole 143 corresponding to the pressure adjusting hole 436 may be formed in the support member 14. The hole 142 extends from a surface of the support member 14 on the +Z side to the vicinity of the center in the −Z direction. The hole 143 extends from an end of the hole 142 on the −Z side to the outer surface of the support member 14 in the XY direction. The pressure adjusting hole 436 communicates with space outside the support member 14 (atmospheric pressure space) via the hole 142 and the hole 143. This enables the pressure of the recessed space SP12 of the region RG2 to be set to approximately an atmospheric pressure (e.g., 10 Pa) at the time when the bonded body CB is adsorbed, and enables the pressure of the recessed space SP12 of the region RG2 to be relatively increased as compared to the pressure of space SP11 corresponding to the region RG1. The pressure adjusting hole 436 is releasable to the atmosphere.

Not one pressure adjusting hole 436 in FIGS. 18 to 22 but multiple pressure adjusting holes 436 may be arranged in the main body portion 4131 in the region RG2.

In the adsorption stage 10, the partition wall 417 is disposed on the main surface 413a between the recessed space SP11 of the region RG1 and the recessed space SP12 of the region RG2. The partition wall 417 is disposed on the main surface 413a between the multiple support pins 11 and the multiple support pins 12. The partition wall 417 may have a Z height equal to the Z height h11 of each of the support pins 11, may have a Z height equal to the Z height h12 of each of the support pins 12, or may have a Z height equal to the Z height of the partition wall 18. The partition wall 417 may have a top surface extending flat along the main surface 413a. Each of the support pins 11 may have a top surface extending flat along the main surface 413a. Each of the support pins 12 may have a top surface extending flat along the main surface 413a. The partition wall 18 may have a top surface extending flat along the main surface 413a. This enables the recessed space SP11 of the region RG1 and the recessed space SP12 of the region RG2 to be spatially separated from each other at the time when the bonded body CB is adsorbed.

The partition wall 417 annularly extends along the boundary between the region RG1 and the region RG2 in XY plan view. The partition wall 417 surrounds the multiple support pins 12 in XY plan view. The partition wall 417 may have a substantially annular shape in XY plan view. The partition wall 417 may have a maximum XY width (e.g., diameter in XY plan view) L417 of 50 mm or less, for example, 5 to 50 mm. The partition wall 417 may have an XY thickness W417 of approximately 1 mm. This enables the recessed space SP11 of the region RG1 and the recessed space SP12 of the region RG2 to be spatially separated from each other at the time when the bonded body CB is adsorbed.

For example, when the bonded body CB is carried to the +Z side of the adsorption stage 410 and placed on the adsorption surface 10a by a conveyance device (not illustrated) or the like, the controller 60 controls the vacuum device 50 to adsorb the bonded body CB to the adsorption surface 10a. In this case, the adsorption stage 410 adsorbs the bonded body CB to the adsorption surface 10a such that the recessed space SP11 of the region RG1 can be selectively depressurized (see FIG. 19). The controller 60 may gradually and relatively move the housing 23 from the XY position on the outer peripheral side of the adsorption surface 10a to the XY position on the center side with the driver 40 while rotating the adsorption stage 10 and the bonded body CB about the Z axis with the driver 30. In this case, a laser beam may be applied from the light source 21 to the bonded body CB through the optical system 22 with a predetermined period. When the housing 23 reaches an XY position in the region RG2, the controller 60 may control the optical system 22 to reciprocate the XY application position of a laser beam in the XY direction in the region RG2. This enables the light source 21 to periodically apply a laser beam while sequentially passing through the region RG1 and the region RG2 along a predetermined track (see FIGS. 11A to 11D).

As described above, in the second embodiment, in the substrate peeling device 401, the adsorption stage 410 can selectively depressurize the recessed space SP11 of the region RG1, and can relatively increase the pressure of recessed space SP12 of the region RG2 compared to the pressure of the recessed space SP11 of the region RG1. This can reduce tensile stress headed from the bonded body CB toward the adsorption stage 10 in the region RG2 at the time when the bonded body CB is adsorbed as compared to tensile stress headed from the bonded body CB toward the adsorption stage 10 in the region RG1. As a result, in the adsorption stage 410, power of adsorbing the bonded body CB in the region RG2 can be weaker than power of adsorbing the bonded body CB in the region RG1. As a result, when a laser beam is periodically applied while sequentially passing through the region RG1 and the region RG2 along a predetermined track and the substrate peeling device 401 performs laser peeling, stress between the substrates SB1 and SB2 can be relaxed at the time when peeling is performed in the region RG2, a gouge and the like of the substrates SB can be suppressed, and one of the substrates SB1 and SB2 of the bonded body CB can be appropriately peeled off the other.

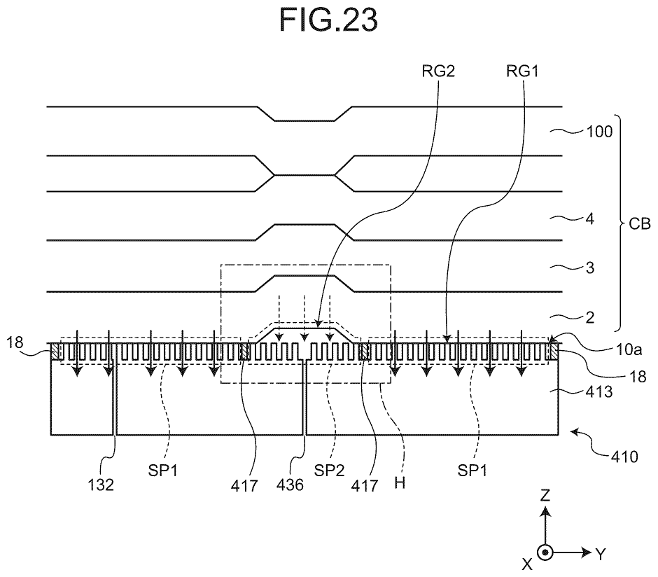

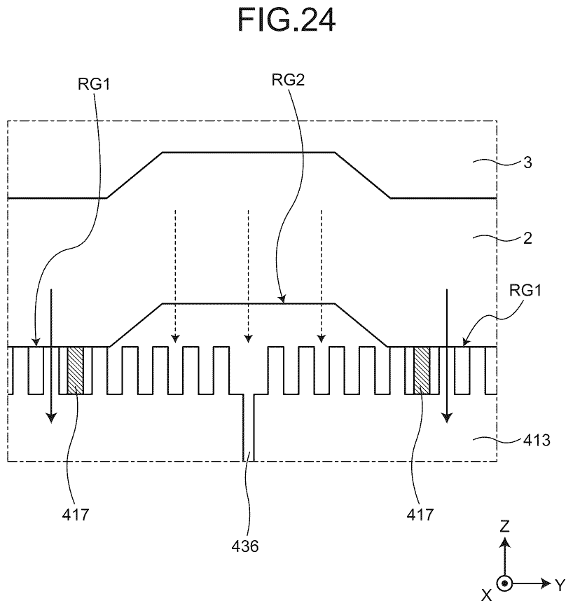

Note that the substrate peeling device 1 may be applied to a method of manufacturing a semiconductor device 300 as illustrated in FIGS. 6 to 13C, 23, 24, 16A to 17. FIG. 23 is a YZ cross-sectional view illustrating stress relaxation in the variation of the second embodiment. FIG. 24 is a YZ enlarged cross-sectional view illustrating stress relaxation in a variation of the second embodiment, and corresponds to a YZ cross section obtained by enlarging a portion H in FIG. 23.

Processes up to S6 in FIG. 6 are performed similarly to those in the variation of the first embodiment. When S6 in FIG. 6 is completed, the conveyance device (not illustrated) or the like carries the bonded body CB to the +Z side of the adsorption stage 410 of the substrate peeling device 401 (see FIG. 18), and places the bonded body CB on the adsorption surface 10a. The substrate peeling device 401 controls the vacuum device 50 to adsorb the bonded body CB to the adsorption surface 10a. In this case, the adsorption stage 10 adsorbs the bonded body CB to the adsorption surface 10a such that space SP12 corresponding to the region RG2 in the adsorption surface 10a has a pressure higher than the pressure of the space SP11 corresponding to the region RG1 (see FIG. 19). In this state, the substrate peeling device 401 applies the laser beam 200 from the side of the substrate 100 to the bonded body CB such that the focal point is located in the vicinity of the film 4 (S7).

In S7, as in the variation of the first embodiment, laser beams 200 of the first to (N−1)th applications are applied.

Thereafter, as illustrated in FIG. 13B, the substrate peeling device 401 determines the final XY plane position where a laser beam 200-N of the Nth application is to be applied, and adjusts the focal point of the laser beam 200-N to be located in the film 4. The final XY plane position may be the final position along the zigzag track (see FIG. 11D). The film 4 has a rate of absorption of the laser beam 200-N larger than a rate of absorption of the laser beam 200-N of the substrate 100. This causes the laser beam 200-N applied to the film 4 through the substrate 100 to be efficiently absorbed at an application portion in the film 4, and causes local heat generation (local heating) in the film 4 at the final XY plane position.

As illustrated in FIG. 13C, the locally generated heat of the film 4 is transmitted to the interface between the film 4 and the substrate 100. The substrate 100 has a thermal expansion coefficient larger than that of the film 4. Therefore, the substrate 100 expands to the side of the film 4 at the final XY plane position, which forms the protrusion 101 in which the substrate 100 protrudes to the side of the film 4. The recess 102 is formed around the protrusion 101. This generates compression stress at the interface between the tip of the protrusion 101 and the film 4 while generating tensile stress at the interface between the bottom surface of the recess 102 and the film 4. The film 4 and the substrate 100 can be partially peeled around the final XY plane position.

In this case, as illustrated in FIGS. 23 and 24, the recessed space SP12 of the region RG2 in the adsorption stage 10 communicates with atmospheric pressure space via the pressure adjusting hole 436 while the recessed space SP11 of the region RG1 is evacuated via the vacuum hole 132 (see FIG. 18). That is, the adsorption stage 410 adsorbs the bonded body CB to the adsorption surface 10a such that the recessed space SP12 of the region RG2 has a pressure higher than the pressure of the recessed space SP11 of the region RG1 (see FIG. 19). As a result, in the adsorption stage 410, power of adsorbing the bonded body CB in the region RG2 can be weaker than power of adsorbing the bonded body CB in the region RG1. In FIGS. 23 and 24, stress in the region RG2 is indicated by a dotted arrow, and stress in the region RG1 is indicated by a solid arrow. The dotted arrow indicates smaller stress than the solid arrow.

For example, in a state where the film 4 and the substrate 100 are partially connected to each other at a portion corresponding to the region RG2 as illustrated in FIGS. 23 and 24, tensile stress in a −Z direction caused by adsorption from the adsorption stage 10 and tensile stress in a +Z direction caused by deformation of the substrate 100 can act on the connection portion. Here, since tensile stress of the region RG2 on the adsorption surface 10a of the adsorption stage 10 is smaller than tensile stress of the region RG1, the connection portion between the film 4 and the substrate 100 in the vicinity of the final XY plane position can be gradually peeled. This can suppress a defect such as a gouge from being generated at the final peeling portion corresponding to the region RG2 of each of the film 4 and the substrate 100.

As partial peeling gradually progresses, peeling is performed at the interface between the film 4 and the substrate 100 (S9). That is, as illustrated in FIG. 16A, the substrate 100 is peeled off a stacked body 6 in which the films 3 and 4 are stacked on the substrate 2.

Thereafter, processing similar to that of the variation of the first embodiment is performed.

In this way, the substrate 100 in the bonded body CB can be appropriately peeled off the stacked body 6 in which the films 3 and 4 are stacked on the substrate 2 by applying the substrate peeling device 401 to the method of manufacturing the semiconductor device 300 in FIGS. 6 to 13C, 23, 24, 16A to 17.

### Third Embodiment

Next, a method of manufacturing the semiconductor device 300 in a third embodiment will be described. Portions different from those of the variation of the first embodiment and the variation of the second embodiment will be mainly described below.

Although, in the variation of the first embodiment and the variation of the second embodiment, the methods of manufacturing the semiconductor device 300 using an adsorption stage having a devised structure have been illustrated, a method of manufacturing the semiconductor device 300 with a devised condition of application of a laser beam will be illustrated in the third embodiment.

When a substrate is peeled off the bonded body CB with a laser beam, energy of laser application in the region RG2 is lowered as compared to energy of laser application in the region RG1. In this case, a pitch of laser application in the region RG2 may be narrower than a pitch of laser application in the region RG1. This enables a connection portion in the vicinity of the final XY plane position on a peeling interface to be gradually peeled while suppressing a reduction in processing capacity in the region RG2 as compared to that in the region RG1, which can suppress a defect such as a gouge from being generated at the peeling interface.

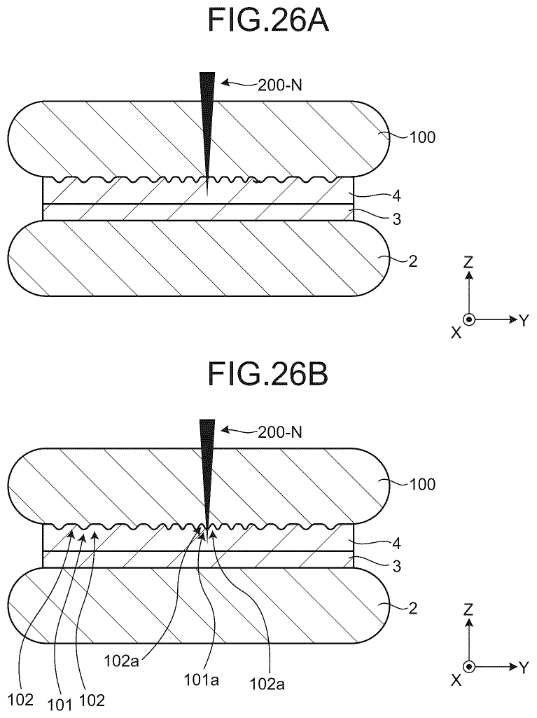

The method of manufacturing the semiconductor device 300 may be performed by using a substrate peeling device 501 (not illustrated) as illustrated in FIGS. 6 to 10, 25A to 25D, 12A to 13A, 26A, 26B, and 16A to 17. FIGS. 25A to 25D are XY plan views illustrating the method of manufacturing the semiconductor device 300 in the third embodiment. FIGS. 26A and 26B are YZ cross-sectional views illustrating the method of manufacturing the semiconductor device 300 in the third embodiment.

The substrate peeling device 501 may be obtained by changing the substrate peeling device 1 (see FIG. 1) such that the main surface 13a of a stage base 513 on the +Z side is entirely changed to be flat and the support pins 11 are arranged instead of the support pins 12 in a region 13a2. In the substrate peeling device 501, the adsorption surface 10a is flat in both the region RG1 and the region RG2 in an adsorption stage 510.

Processes up to S6 in FIG. 6 are performed similarly to those in the variation of the first embodiment. When S6 in FIG. 6 is completed, the substrate peeling device 501 applies the laser beam 200 from the side of the substrate 100 to the bonded body CB such that the focal point is located in the vicinity of the film 4 (S7).

The substrate peeling device 501 applies the laser beam 200 such that multiple application portions are two-dimensionally distributed in the film 4 as illustrated in FIGS. 25A to 25D. The substrate peeling device 501 may apply the laser beam 200 while changing a condition in multiple stages. As illustrated in FIG. 25C, the region RG1 in the adsorption stage 510 is divided into an outer region RG11 and an inner region RG12. FIGS. 25A to 25D illustrate a case where the substrate peeling device 501 applies the laser beam 200 while changing a condition in three stages of the region RG11→ the region RG12→ the region RG2. FIG. 25D is an XY enlarged plan view illustrating the enlarged region RG12 and region RG2 in FIG. 25C. In FIG. 25D, the magnitude of pulse energy of a laser beam is indicated by the magnitude of a point.

In application of a laser to the region RG11 in FIG. 25A, the substrate peeling device 501 relatively moves the laser module 20 from the outer periphery gradually to the inner peripheral side in the adsorption stage 510 while rotating the adsorption stage 510 at a gradually increasing rotation speed. This causes the substrate peeling device 501 to move the portions of application of the laser beam 200 along a spiral track headed from the outer periphery gradually to the inner periphery in the region RG11. The laser beam may have a pulse frequency of a fixed value of, for example, 10 to 100 kHz. The laser beam may have pulse energy PE1 of 100 mj. The application portions may have a pitch PP1 of 15 μm. The application portions may have a radius of 12 mm or less. The rotation speed of the adsorption stage 510 may be adjusted so as to gradually increase in a range of 0.80 to 47.8 rotations/second.

For example, as in the variation of the first embodiment, laser beams of the first to kth applications are applied.

In application of a laser to the region RG12 in FIGS. 25B to 25D, the substrate peeling device 501 relatively moves the laser module 20 from the outer periphery gradually to the inner peripheral side in the adsorption stage 510 while rotating the adsorption stage 510 at a fixed rotation speed. This causes the substrate peeling device 501 to move the portions of application of the laser beam 200 along a spiral track headed from the outer periphery gradually to the inner periphery in the region RG12. The laser beam may have a gradually increasing pulse frequency in a range of, for example, 10 to 100 kHz. The laser beam may have pulse energy PE1 of 100 mj. The application portions may have a pitch PP2 smaller than PP1. The application portions may have a gradually decreasing radius in a range of 12 to 2.5 mm. The adsorption stage 10 may have a fixed rotation speed of 47.8 rotations/second.

For example, as in the variation of the first embodiment, laser beams of the (k+1)th to jth applications are applied.

In application of a laser to the region RG2 in FIGS. 25C and 25D, the substrate peeling device 501 relatively moves the laser module 20 from the outer periphery gradually to the inner peripheral side in the adsorption stage 510 while rotating the adsorption stage 510 at a fixed rotation speed. This causes the substrate peeling device 501 to move the portions of application of the laser beam 200 along a spiral track in the region RG2. The laser beam may have a fixed pulse frequency in a range of, for example, 10 to 100 kHz. The laser beam may have pulse energy PE2 smaller than PE1, for example, 50 mj. The application portions may have a pitch PP3 smaller than PP2. The application portions may have a gradually decreasing radius in a range of 2.5 to 0.1 mm.

Although not illustrated, the substrate peeling device 501 determines an XY plane position where a laser beam 200-(j+1) of the (j+1)th application immediately after arrival at the region RG12 is to be applied to a position shifted from the XY plane position of the jth application in the XY plane direction, and adjusts the focal point of the laser beam 200-(j+1) to be located in the film 4. This causes the laser beam 200-(j+1) applied to the film 4 through the substrate 100 to be efficiently absorbed at an application portion in the film 4, and causes local heat generation (local heating) in the film 4 at the XY plane position.

The locally generated heat of the film 4 is transmitted to the interface between the film 4 and the substrate 100. The substrate 100 has a thermal expansion coefficient larger than that of the film 4. Therefore, the substrate 100 expands to the side of the film 4 at the XY plane position, which forms a protrusion 101a in which the substrate 100 protrudes to the side of the film 4. A recess 102a is formed around the protrusion 101a. The protrusion 101a has an XY plane dimension smaller than that of a protrusion 101 in each of the regions RG11 and RG12. The protrusion 101a has a Z height lower than that of a protrusion 101 in the regions RG11 and RG12. The recess 102a has an XY plane dimension smaller than that of a recess 102 in each of the regions RG11 and RG12. The recess 102a has a Z depth shallower than that of a recess 102 in each of the regions RG11 and RG12.

This generates compression stress at the interface between the tip of the protrusion 101a and the film 4 while generating tensile stress at the interface between the bottom surface of the recess 102a and the film 4. The film 4 and the substrate 100 can be partially peeled around the XY plane position. In this case, since compression stress at the interface between the tip of the protrusion 101a and the film 4 and tensile stress at the interface between the bottom surface of the recess 102a and the film 4 are smaller than those at the time of peeling in the regions RG11 and RG12, the film 4 and the substrate 100 can be peeled more mildly around the XY plane position.

As illustrated in FIG. 26A, the substrate peeling device 501 determines the final XY plane position where a laser beam 200-N of the Nth application is to be applied, and adjusts the focal point of the laser beam 200-N to be located in the film 4. This causes the laser beam 200-N applied to the film 4 through the substrate 100 to be efficiently absorbed at an application portion in the film 4, and causes local heat generation (local heating) in the film 4 at the final XY plane position.

As illustrated in FIG. 26B, the locally generated heat of the film 4 is transmitted to the interface between the film 4 and the substrate 100. The substrate 100 has a thermal expansion coefficient larger than that of the film 4. Therefore, the substrate 100 expands to the side of the film 4 at the final XY plane position, which forms a protrusion 101a in which the substrate 100 protrudes to the side of the film 4. A recess 102a is formed around the protrusion 101a. The protrusion 101a has an XY plane dimension smaller than that of a protrusion 101 in each of the regions RG11 and RG12. The protrusion 101a has a Z height lower than that of a protrusion 101 in the regions RG11 and RG12. The recess 102a has an XY plane dimension smaller than that of a recess 102 in each of the regions RG11 and RG12. The recess 102a has a Z depth shallower than that of a recess 102 in each of the regions RG11 and RG12.

This generates compression stress at the interface between the tip of the protrusion 101a and the film 4 while generating tensile stress at the interface between the bottom surface of the recess 102a and the film 4. The film 4 and the substrate 100 can be partially peeled around the final XY plane position. In this case, since compression stress at the interface between the tip of the protrusion 101a and the film 4 and tensile stress at the interface between the bottom surface of the recess 102a and the film 4 are smaller than those at the time of peeling in the regions RG11 and RG12, the film 4 and the substrate 100 can be peeled more mildly around the XY plane position.

That is, since tensile stress of the region RG2 in the adsorption stage 510 is smaller than tensile stress of the region RG1, the connection portion between the film 4 and the substrate 100 in the vicinity of the final XY plane position can be gradually peeled. This can suppress a defect such as a gouge from being generated at the final peeling portion corresponding to the region RG2 of each of the film 4 and the substrate 100.

As partial peeling gradually progresses, peeling is performed at the interface between the film 4 and the substrate 100 (S9). That is, as illustrated in FIG. 16A, the substrate 100 is peeled off a stacked body 6 in which the films 3 and 4 are stacked on the substrate 2.

Thereafter, processing similar to that of the variation of the first embodiment is performed.

As described above, in the third embodiment, when a substrate is peeled off the bonded body CB with a laser beam, energy of laser application in the region RG2 is lowered compared to energy of laser application in the region RG1. In this case, a pitch of laser application in the region RG2 may be narrower than a pitch of laser application in the region RG1. This enables a connection portion in the vicinity of the final XY plane position on a peeling interface to be gradually peeled while suppressing a reduction in processing capacity in the region RG2 as compared to that in the region RG1, which can suppress a defect such as a gouge from being generated at the peeling interface.

Addition 21. A method of manufacturing a semiconductor device, comprising:

obtaining a stacked body in which a second film and a first film are stacked on a second substrate by peeling a first substrate off a bonded body by the substrate peeling method according to addition 14; and obtaining a semiconductor device by flattening a peeling surface of the stacked body.

Addition 22. A method of manufacturing a semiconductor device, comprising:
obtaining a stacked body in which a second film and a first film are stacked on a second substrate by peeling a first substrate off a bonded body by the substrate peeling method according to addition 17; and
obtaining a semiconductor device by flattening a peeling surface of the stacked body.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate peeling device comprising:
an adsorption stage configured to adsorb a bonded body including multiple substrates and that includes a first region and a second region inside the first region; and
a light source configured to sequentially apply a laser beam toward the first region and the second region,
wherein the adsorption stage has weaker power of adsorbing the bonded body in the second region than in the first region.

2. The substrate peeling device according to claim 1,
wherein the adsorption stage includes:
a stage base having a main surface including a flat surface disposed in the first region, and
a protruding surface disposed in the second region and protruding from the flat surface.

3. The substrate peeling device according to claim 2,
wherein the protruding surface protrudes from the flat surface and the protruding surface having a curved surface shape.

4. The substrate peeling device according to claim 2,
wherein the adsorption stage includes:
multiple first pins arranged on the flat surface and each having a first height;
multiple second pins arranged on the protruding surface and each having the first height; and
a partition wall disposed on an outer peripheral side of the flat surface and having the first height.

5. The substrate peeling device according to claim 4,
wherein each of the first pins has a top surface extending flat along the flat surface, and
each of the second pins has a top surface extending in a protruding manner along the protruding surface.

6. The substrate peeling device according to claim 4,
wherein the protruding surface protrudes from the flat surface and the protruding surface having a curved surface shape,
each of the first pins has a top surface extending flat along the flat surface.

7. The substrate peeling device according to claim 2,
wherein the stage base has a hole extending from the flat surface to a bottom surface opposite to the flat surface in the first region.

8. The substrate peeling device according to claim 1,
wherein the adsorption stage has a pressure of space corresponding to the second region higher than a pressure of space corresponding to the first region.

9. The substrate peeling device according to claim 8,
wherein the stage base has: a first hole extending from the main surface to a bottom surface opposite to the main surface in the first region and allowed to be evacuated; and a second hole extending from the main surface to a bottom surface opposite to the main surface in the second region and releasable to an atmosphere.

10. The substrate peeling device according to claim 8,
wherein the adsorption stage includes:
a stage base including a main surface disposed in the first region and the second region and a hole extending from the main surface to a bottom surface opposite to the main surface in the second region;
multiple first pins arranged on the main surface in the first region and each having a first height;
multiple second pins arranged on the main surface in the second region and each having the first height;
a first partition wall disposed on the main surface on an outer peripheral side of the first region and having the first height; and
a second partition wall disposed on the main surface at a boundary between the first region and the second region and having the first height.

11. The substrate peeling device according to claim 10,
wherein the main surface extends flat,
each of the first pins has a top surface extending flat along the main surface;
the first partition wall has a top surface extending flat along the main surface;
each of the second pins has a top surface extending flat along the main surface; and
the second partition wall has a top surface extending flat along the main surface.

12. The substrate peeling device according to claim 2,
wherein the second region has a maximum plane width of 10 mm or less.

13. The substrate peeling device according to claim 10,
wherein the second region has a maximum plane width of 50 mm or less.

14. A substrate peeling method comprising:
preparing a first substrate;
stacking a first film on the first substrate;
stacking a second film on a second substrate;
forming a bonded body by bonding a main surface opposite to the first substrate in the first film and a main surface opposite to the second substrate in the second film with each other;
applying a laser beam from a side of the first substrate to the bonded body with the bonded body being adsorbed to an adsorption stage; and
peeling the first substrate off the bonded body,
wherein the adsorption stage includes a first region and a second region inside the first region, and has weaker power of adsorbing the bonded body in the second region than in the first region, and
applying the laser beam toward the second region after applying the laser beam toward the first region.

15. The substrate peeling method according to claim 14, further comprising:
applying the laser beam toward the first region with the bonded body being adsorbed to the adsorption stage including a stage base having a main surface including a flat surface disposed in the first region and a protruding surface disposed in the second region and protruding from the flat surface; and
applying the laser beam toward the second region with the bonded body being adsorbed to the adsorption stage including the stage base after the applying to the first region.

16. The substrate peeling method according to claim 14, further comprising: applying the laser beam toward the first region with a pressure of space corresponding to the second region being higher than a pressure of space corresponding to the first region; and
applying the laser beam toward the second region with a pressure of space corresponding to the second region being higher than a pressure of space corresponding to the first region after the applying to the first region.

17. A substrate peeling method comprising:
preparing a first substrate;
stacking a first film on the first substrate;
stacking a second film on a second substrate;
forming a bonded body by bonding a main surface opposite to the first substrate in the first film and a main surface opposite to the second substrate in the second film with each other;
applying a laser beam from a side of the first substrate to the bonded body with the bonded body being adsorbed to an adsorption stage; and
peeling the first substrate off the bonded body,
wherein the adsorption stage includes a first region and a second region inside the first region, and
the applying includes:
applying the laser beam toward the first region with first energy; and
applying the laser beam toward the second region with second energy smaller than the first energy after the applying to the first region.

18. The substrate peeling method according to claim 17, further comprising: applying the laser beam with first energy while moving a portion of application of the laser beam at a first pitch along a track in the first region; and
applying the laser beam with second energy smaller than the first energy while moving the portion of application of the laser beam at a second pitch smaller than the first pitch along a track in the second region after the applying to the first region.

19. The substrate peeling method according to claim 14, further comprising:
obtaining a stacked body in which a second film and a first film are stacked on the second substrate by peeling the first substrate off the bonded body; and
obtaining a semiconductor device by flattening a peeling surface of the stacked body.

20. The substrate peeling method according to claim 17, further, comprising:
obtaining a stacked body in which a second film and a first film are stacked on the second substrate by peeling the first substrate off the bonded body; and
obtaining a semiconductor device by flattening a peeling surface of the stacked body.
